(19) United States
(12) Patent Application Publication
(10) Pub. No.: US 2026/0247727 A1
(43) Pub. Date: Aug. 20, 2026

(54) LIGHT DETECTING DEVICE AND ELECTRONIC APPARATUS

(71) Applicant: SONY SEMICONDUCTOR SOLUTIONS CORPORATION, Kanagawa (JP)

(72) Inventors: Kohei SAKANASHI, Tokyo (JP); Shinichi MIYAKE, Kanagawa (JP)

(73) Assignee: SONY SEMICONDUCTOR SOLUTIONS CORPORATION, Kanagawa (JP)

(21) Appl. No.: 19/471,596

(22) PCT Filed: Jan. 19, 2024
(86) PCT No.: PCT/JP2024/001396

§ 371 Date: Oct. 1, 2025

(30) Foreign Application Priority Data
Apr. 12, 2023 (JP) 2023-065186
Dec. 5, 2023 (JP) 2023-205645

(51) Int. Cl. H10F 39/00; H04N 25/772; H04N 25/78

(52) U.S. Cl. CPC H10F 39/8023; H04N 25/772; H04N 25/78; H10F 39/80373; H10F 39/8063; H10F 39/811

(57) ABSTRACT

A light detecting device according to an embodiment of the present disclosure includes a first substrate and a second substrate. The first substrate includes a photoelectric conversion element and a readout circuit. The photoelectric conversion element photoelectrically converts light. The readout circuit is configured to output a first signal based on electric charge converted by the photoelectric conversion element. The second substrate includes a signal processing circuit configured to execute signal processing on the first signal. The second substrate is stacked on the first substrate. The first substrate includes a semiconductor layer and a wiring layer. The readout circuit includes a first transistor provided in the wiring layer.

### TECHNICAL FIELD

The present disclosure relates to a light detecting device and an electronic apparatus.

### BACKGROUND ART

There has been proposed an imaging device that has a stacked structure formed by pasting together three substrates which are a sensor substrate, a pixel transistor substrate, and a logic substrate (PTL 1).

### CITATION LIST

### Patent Literature

PTL 1: International Publication No. WO2020/262582.

### SUMMARY OF THE INVENTION

It is desirable for devices that detect light to enable miniaturization.

It is desired to provide a light detecting device having an advantage in miniaturization.

A light detecting device according to an embodiment of the present disclosure includes a first substrate and a second substrate. The first substrate includes a photoelectric conversion element and a readout circuit. The photoelectric conversion element photoelectrically converts light. The readout circuit is configured to output a first signal based on electric charge converted by the photoelectric conversion element. The second substrate includes a signal processing circuit configured to execute signal processing on the first signal. The second substrate is stacked on the first substrate. The first substrate includes a semiconductor layer and a wiring layer. The readout circuit includes a first transistor provided in the wiring layer.

An electronic apparatus according to an embodiment of the present disclosure includes an optical system and a light detecting device that receives light transmitted though the optical system. The light detecting device includes a first substrate and a second substrate. The first substrate includes a photoelectric conversion element and a readout circuit. The photoelectric conversion element photoelectrically converts light. The readout circuit is configured to output a first signal based on electric charge converted by the photoelectric conversion element. The second substrate includes a signal processing circuit configured to execute signal processing on the first signal. The second substrate is stacked on the first substrate. The first substrate includes a semiconductor layer and a wiring layer. The readout circuit includes a first transistor provided in the wiring layer.

### BRIEF DESCRIPTION OF THE DRAWINGS

FIG. 1 is a block diagram illustrating an example of a schematic configuration of an imaging device that is an example of a light detecting device according to a first embodiment of the present disclosure.

FIG. 2 is a diagram illustrating an example of a pixel section of the imaging device according to the first embodiment of the present disclosure.

FIG. 3 is an explanatory diagram of an example of a circuit configuration of pixels of the imaging device according to the first embodiment of the present disclosure.

FIG. 4 is an explanatory diagram of an example of a cross-sectional configuration of the imaging device according to the first embodiment of the present disclosure.

FIG. 5 is a diagram illustrating an example of a cross-sectional configuration of the imaging device according to the first embodiment of the present disclosure.

FIG. 6 is an explanatory diagram of an example of a planar configuration of the imaging device according to the first embodiment of the present disclosure.

FIG. 7 is an explanatory diagram of an example of a planar configuration of the imaging device according to the first embodiment of the present disclosure.

FIG. 8 is an explanatory diagram of another example of a planar configuration of the imaging device according to the first embodiment of the present disclosure.

FIG. 9A is an explanatory diagram of a configuration example of an imaging device according to Modification Example 1 of the present disclosure.

FIG. 9B is an explanatory diagram of a configuration example of an imaging device according to Modification Example 1 of the present disclosure.

FIG. 10 is an explanatory diagram of a configuration example of an imaging device according to Modification Example 2 of the present disclosure.

FIG. 11 is an explanatory diagram of the configuration example of the imaging device according to Modification Example 2 of the present disclosure.

FIG. 12 is an explanatory diagram of an example of a cross-sectional configuration of an imaging device according to a second embodiment of the present disclosure.

FIG. 13 is an explanatory diagram of an example of a planar configuration of the imaging device according to the second embodiment of the present disclosure.

FIG. 14 is an explanatory diagram of a configuration example of an imaging device according to Modification Example 4 of the present disclosure.

FIG. 15 is an explanatory diagram of the configuration example of the imaging device according to Modification Example 4 of the present disclosure.

FIG. 16 is an explanatory diagram of another configuration example of the imaging device according to Modification Example 4 of the present disclosure.

FIG. 17 is an explanatory diagram of the other configuration example of the imaging device according to Modification Example 4 of the present disclosure.

FIG. 18 is an explanatory diagram of a configuration example of an imaging device according to Modification Example 5 of the present disclosure.

FIG. 19 is an explanatory diagram of another configuration example of the imaging device according to Modification Example 5 of the present disclosure.

FIG. 20 is a block diagram illustrating a configuration example of an electronic apparatus including the imaging device.

FIG. 21 is a block diagram depicting an example of schematic configuration of a vehicle control system.

FIG. 22 is a diagram of assistance in explaining an example of installation positions of an outside-vehicle information detecting section and an imaging section.

FIG. 23 is a view depicting an example of a schematic configuration of an endoscopic surgery system.

FIG. 24 is a block diagram depicting an example of a functional configuration of a camera head and a camera control unit (CCU).

### MODES FOR CARRYING OUT THE INVENTION

Next, with reference to drawings, details of embodiments of the present disclosure will be described. It is to be noted that the description will be given in the following order.
1. First Embodiment
2. Modification Examples
3. Second Embodiment
4. Modification Examples
5. Application Example
6. Practical Application Examples

### 1. First Embodiment

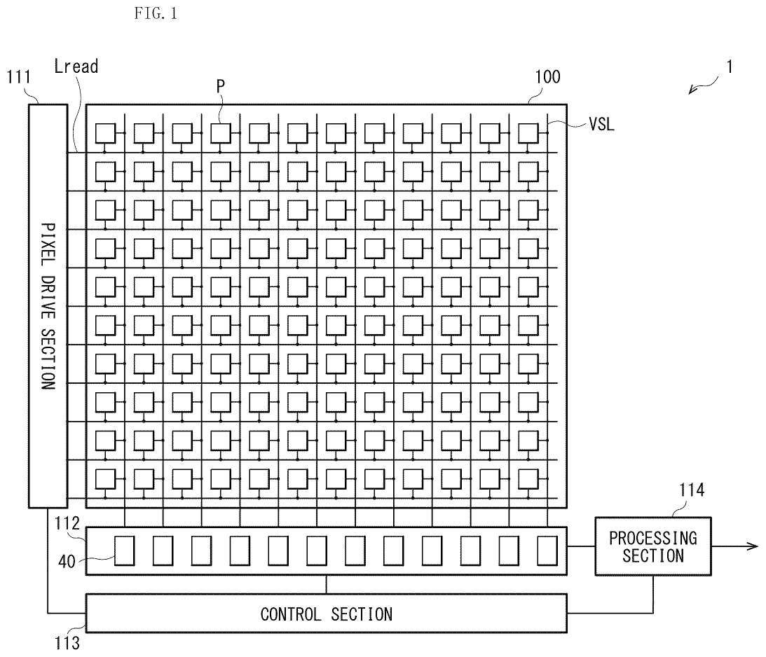

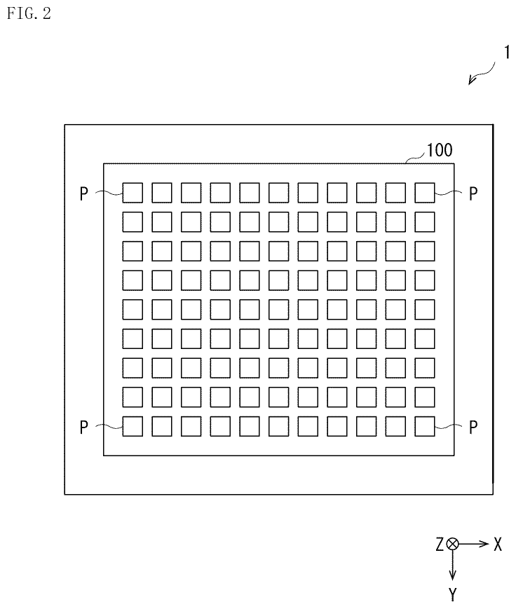

FIG. 1 is a block diagram illustrating an example of a schematic configuration of an imaging device that is an example of a light detecting device according to a first embodiment of the present disclosure. FIG. 2 is a diagram illustrating an example of a pixel section of the imaging device according to the first embodiment. The light detecting device is a device that makes it possible to detect incident light. An imaging device 1 serving as the light detecting device includes a plurality of pixels P having photoelectric conversion sections photoelectric conversion elements), and is configured to perform photoelectric conversion on incident light and generate a signal. The imaging device (light detecting device) may receive light transmitted through an optical system including an optical lens (unillustrated) and generate a signal.

For example, the imaging device 1 includes a semiconductor substrate (e.g., silicon substrate) provided with the plurality of pixels P. The imaging device 1 includes the pixels P, each of which includes the photoelectric conversion section that is a photodiode and that makes it possible to perform photoelectric conversion on light. As illustrated in FIG. 2, the imaging device 1 includes an imaging area that is a region (pixel section 100) where the plurality of pixels P is two-dimensionally arranged in a matrix form. The pixel section 100 is a pixel array where the plurality of pixels P is arranged. The pixel section 100 is also referred to as a light receiving region.

The imaging device 1 takes in incident light (image light) from a subject through the optical system including the optical lens. The imaging device 1 captures an image of the subject that is formed by the optical lens. The imaging device 1 may perform photoelectric conversion on received light and generate a pixel signal. For example, the imaging device 1 is a complementary metal-oxide-semiconductor (CMOS) image sensor. The imaging device 1 is applicable to electronic apparatuses such as digital still cameras, video cameras, or mobile phones, for example.

As illustrated in FIG. 2, it is to be noted that a Z-axis direction is an incident direction of light from a subject, an X-axis direction is a left-right direction that is orthogonal to the Z-axis direction on the paper surface, and a Y-axis direction is a top-bottom direction that is orthogonal to the Z-axis and the X-axis on the paper surface. With regard to subsequent drawings, sometimes directions may be described on the basis of the directions of the arrows illustrated in FIG. 2.

As illustrated in the example in FIG. 1, for example, the imaging device 1 includes a pixel drive section 111, a signal processing section 112, a control section 113, a processing section 114, and the like in a region around the pixel section 100 (pixel array). The imaging device 1 is also provided with a plurality of control lines Lread and a plurality of signal lines VSL.

The control lines Lread are signal lines that make it possible to communicate signals to drive the pixels P, and are coupled to the pixel drive section 111 and the pixels P in the pixel section 100. In the example illustrated in FIG. 1, the pixel section 100 is wired with the plurality of control lines Lread installed for respective pixel rows including the plurality of pixels P arranged in a horizontal direction (row direction). The control lines Lread are configured to transmit a control signal for reading out signals from the pixels P.

Each of the plurality of control lines Lread installed for respective pixel rows of the imaging device 1 includes wiring for transmitting a signal for controlling the transfer transistor, wiring for transmitting a signal for controlling the selection transistor, wiring for transmitting a signal for controlling a reset transistor, and the like, for example. It can also be said that, the control lines Lread are drive lines (pixel drive lines) to transmit signals for driving the pixels P.

The signal lines VSL are signal lines that make it possible to communicate signals from the pixels P, and are coupled to the signal processing section 112 and the pixels P of the pixel section 100. For example, the pixel section 100 is wired with the one or more signal lines VSL installed for respective pixel column including the plurality of pixels P arranged in a vertical direction (column direction).

The signal lines VSL are vertical signal lines and are configured to transmit signals output from the pixels P. The imaging device 1 may also be provided with the plurality of signal lines VSL installed for one of the pixel columns. The imaging device 1 may include the plurality of signal lines VSL for the respective pixel columns.

The pixel drive section 111 is configured to drive the respective pixels P of the pixel section 100. The pixel drive section 111 is a drive circuit and is implemented by a plurality of circuits including a buffer, a shift register, an address decoder, and the like, for example. The pixel drive section 111 (pixel drive circuit) generates signals for driving the pixels P and outputs the signals to the respective pixels P of the pixel section 100 through the control lines Lread. The pixel drive section 111 controls the pixels P of the pixel section 100 under the control of the control section 113.

For example, the pixel drive section 111 generates signals for controlling the pixels P such as a signal for controlling the transfer transistor of the pixels P, a signal for controlling the selection transistor, or a signal for controlling the reset transistor, and supplies the signals to each of the pixels P through the control lines Lread. The pixel drive section 111 may perform control to read pixel signals from the respective pixels P. The pixel drive section 111 may also be referred to as a pixel control section that is configured to control the respective pixels P. It is to be noted that a set of the pixel drive section 111 and the control section 113 may be referred to as the pixel control section.

The signal processing section 112 is configured to execute signal processing of signals of the pixels to be inputted. The signal processing section 112 is a signal processing circuit and includes, for example, a load circuit section, an AD conversion section, a horizontal selection switch, or the like. As an example, the load circuit section is implemented by an electric current source that makes it possible to supply electric current to the amplification transistors of the pixels P. For example, the load circuit section and the amplification transistors of the pixels P constitute a source follower circuit. It is to be noted that the signal processing section 112 may include an amplification circuit section configured to amplify signals read from the pixels P through the signal lines VSL.

The signal processing section 112 may include a plurality of AD conversion sections (AD conversion circuits) and output pixels signals converted into digital signals by the AD conversion sections. The AD conversion sections 40 are analog-to-digital converters (ADCs). For example, the AD conversion sections 40 are provided for the respective signal lines VSL. The AD conversion sections 40 may be provided for the respective pixel columns of the pixel section 100.

The AD conversion section 40 is configured to convert inputted analog signals into digital signals. The AD conversion section 40 performs an AD conversion process on signals of the pixels that are analog signals inputted from the respective pixels P through the signal line VSL. As an example, the AD conversion section 40 (AD conversion circuit) may include a comparison circuit (comparator circuit) and a counter to convert the inputted signals of the pixels into a digital signal of a predetermined number of bits.

Signals that are output from the respective pixels P and selected/scanned by the pixel drive section 111 are inputted into the signal processing section 112 through the signal lines VSL. The signal processing section 112 may perform signals processing such as AD conversion of the signals of the pixels P or correlated double sampling (CDS), for example. Signals of the respective pixels P transmitted through the respective signal lines VSL are subjected to the signal processing by the signal processing section 112 and are output to the processing section 114.

The processing section 114 is configured to execute signal processing of inputted signals. The processing section 114 is a processing circuit, and is implemented by a circuit that performs various kinds of signal processing on the pixel signals, for example. The processing section 114 may include a processor and memory. The processing section 114 performs the signal processing on signals of the pixels inputted from the signal processing section 112, and outputs the processed signals of the pixels. The processing section 114, for example, may perform various kinds of signal processing such as a noise reduction process or a gradation correction process.

The control section 113 is configured to control the respective sections of the imaging device 1. The control section 113 may receive a clock, data for commanding an operation mode, or the like that is given from outside, and may also output data such as internal information of the imaging device 1. The control section 113 is a control circuit and includes a timing generator configured to generate various kinds of timing signals, for example.

The control section 113 controls driving of the pixel drive section 111, the signal processing section 112, and the like on the basis of the various kinds of timing signals (pulse signal, clock signal, and the like) generated by the timing generator. It is to be noted that a portion or all of the processing section 114 and the control section 113 may be integrated.

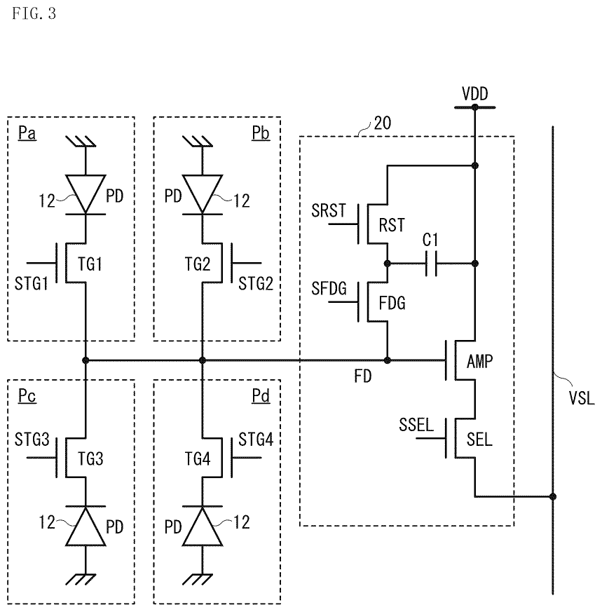

FIG. 3 is an explanatory diagram of an example of a circuit configuration of the pixels of the imaging device according to the first embodiment of the present disclosure. The pixel P of the imaging device 1 includes a photoelectric conversion section 12 (photoelectric conversion element), a transfer transistor TG, a floating diffusion FD, and a readout circuit 20. The photoelectric conversion section 12 is configured to receive light and generate a signal. The photoelectric conversion section 12 is alight reception section (light reception element) configured to generate electric charge through photoelectric conversion.

The readout circuit 20 is configured to output a signal based on the photoelectrically-converted electric charge. As an example, the imaging device 1 includes the readout circuit 20 provided for the plurality of pixels P. The imaging device 1 has a configuration in which the plurality of pixels P shares one readout circuit 20.

In the example illustrated in FIG. 3, the readout circuit 20 is disposed for every four pixels P (referred to as pixel Pa to pixel Pd). The pixels Pa, Pb, Pc, and Pd share one readout circuit 20. For example, 2×2 pixels including adjacent pixels Pa to Pd share one readout circuit 20.

The imaging device 1 may read respective pixel signals from the 2×2 pixels by operating the readout circuit 20 in a time division manner. In addition, it is also possible for the imaging device 1 to read a pixel signal to which the respective pixel signals of the 2×2 pixels are added. It is to be noted that the imaging device 1 may have a configuration in which five or more pixels P such as eight pixels P share one readout circuit 20.

In the example illustrated in FIG. 3, the photoelectric conversion section 12 is a photodiode (PD) and converts incident light into the electric charge. The photoelectric conversion section 12 (photodiode PD in each of the pixels Pa to Pd in FIG. 3) performs photoelectric conversion to generate electric charge corresponding to an amount of received light.

The transfer transistor TG (in FIG. 3, transfer transistor TG1 of pixel Pa to transfer transistor TG4 of pixel Pd) is configured to transfer, to the floating diffusion FD, the electric charge that is photoelectrically converted by the photoelectric conversion section 12. The transfer transistor TG electrically couples or decouples the photoelectric conversion section 12 to/from the floating diffusion FD under the control of a signal STG. The transfer transistor TG may transfer, to the floating diffusion FD, the electric charge that is photoelectrically converted and accumulated in the photoelectric conversion section 12.

In the example illustrated in FIG. 3, ON/OFF control is performed on the respective transfer transistors TG of the pixels Pa to Pd by signals different from each other. The transfer transistor TG1 of the pixel Pa is controlled by a signal STG1, and the transfer transistor TG2 of the pixel Pb is controlled by a signal STG2. In addition, the transfer transistor TG3 of the pixel Pc is controlled by a signal STG3, and the transfer transistor TG4 of the pixel Pd is controlled by a signal STG4.

The floating diffusion FD is an accumulation section configured to accumulate the transferred electric charge. The floating diffusion FD may accumulate the electric charge that is photoelectrically converted by the photoelectric conversion section 12. The floating diffusion FD may also be referred to as a holding section that makes it possible to hold the transferred electric charge. The floating diffusion FD accumulates the transferred electric charge and converts it into a voltage depending on capacitance of the floating diffusion FD.

As an example, as illustrated in FIG. 3, the readout circuit 20 includes an amplification transistor AMP, a selection transistor SEL, a transistor FDG, and a reset transistor RST. The amplification transistor AMP is configured to generate and output a signal based on the electric charge accumulated in the floating diffusion FD. As illustrated in FIG. 3, the amplification transistor AMP has a gate that is electrically coupled to the floating diffusion FD and that receives input of the voltage converted by the floating diffusion FD.

The amplification transistor AMP has a drain that is coupled to an electric power supply line supplied with an electric power supply voltage VDD, and has a source that is coupled to the signal line VSL through the selection transistor SEL. The amplification transistor AMP may generate a signal based on the electric charge accumulated in the floating diffusion FD, that is, a signal based on the voltage of the floating diffusion FD, and may output the generated signal to the signal line VSL. The amplification transistor AMP is configured to generate a signal based on the electric charge converted by the photoelectric conversion section 12.

The selection transistor SEL is configured to control output of a signal from the pixel. The selection transistor SEL is configured to output a signal from the amplification transistor AMP to the signal line VSL under the control of a signal SSEL. The selection transistor SEL may control an output timing of the signal of the pixel. The selection transistor SEL is configured to output a signal based on the electric charge converted by the photoelectric conversion section 12. It is to be noted that the selection transistor SEL may be installed between the amplification transistor AMP and the electric power supply line supplied with the electric power supply voltage VDD. Alternatively, the selection transistor SEL may be omitted if necessary.

As an example, the transistor FDG is installed between the floating diffusion FD and the reset transistor RST. The transistor FDG is configured to electrically couple the floating diffusion FD and a capacitor C1. For example, the transistor FDG electrically couples or decouples the floating diffusion FD to/from the capacitor C1 under the control of a signal SFDG.

When turning on the transistor FDG, a larger capacitance is added to the floating diffusion FD of the pixel P and it becomes possible to change a conversion efficiency (gain) in converting the electric charge into the voltage. The transistor FDG is a switching transistor that switches the capacitance coupled to the gate of the amplification transistor AMP to change the conversion efficiency.

The reset transistor RST is configured to reset the voltage of the floating diffusion FD. In the example illustrated in FIG. 3, the reset transistor RST is configured to be electrically coupled to the electric power supply line supplied with the electric power supply voltage VDD, and to reset the electric charge of the pixel P.

The reset transistor RST may reset the electric charge accumulated in the floating diffusion FD and reset the voltage of the floating diffusion FD under the control of a signal SRST. It is to be noted that the reset transistor RST may discharge the electric charge accumulated in the photoelectric conversion section 12, through the transistor FDG and the transfer transistor TG.

Each of the transfer transistor TG, the amplification transistor AMP, the selection transistor SEL, the transistor FDG (switching transistor), and the reset transistor RST is an MOS transistor (MOSFET) having gate, source, and drain terminals.

In the example illustrated in FIG. 3, each of the transfer transistor TG, the amplification transistor AMP, the selection transistor SEL, the transistor FDG, and the reset transistor RST is implemented by an NMOS transistor. It is to be noted that the transistors of the pixels P may be implemented by PMOS transistors.

The pixel drive section 111 (see FIG. 1) supplies control signals to the gates of the transfer transistors TG, the selection transistors SEL, the transistor FDG, the reset transistors RST, and the like of the respective pixels P through the above-described control lines Lread, and puts the transistors into an ON state (conductive state) or an OFF state (nonconductive state).

The plurality of control lines Lread of the imaging device 1 includes wiring for transmitting the signal STG to control the transfer transistors TG, wiring for transmitting the signal SSEL to control the selection transistors SEL, wiring for transmitting the signal SFDG to control the transistor FDG, wiring for transmitting the signal SRST to control the reset transistors RST, and the like.

The pixel drive section 111 performs ON/OFF control on the transfer transistors TG, the selection transistor SEL, the transistor FDG, the reset transistor RST, and the like. The pixel drive section 111 controls the readout circuit 20 of the respective pixels P to cause the pixels P to output the pixel signals to the signal lines VSL. The pixel drive section 111 may perform control to read the pixel signals from the respective pixels P to the signal lines VSL.

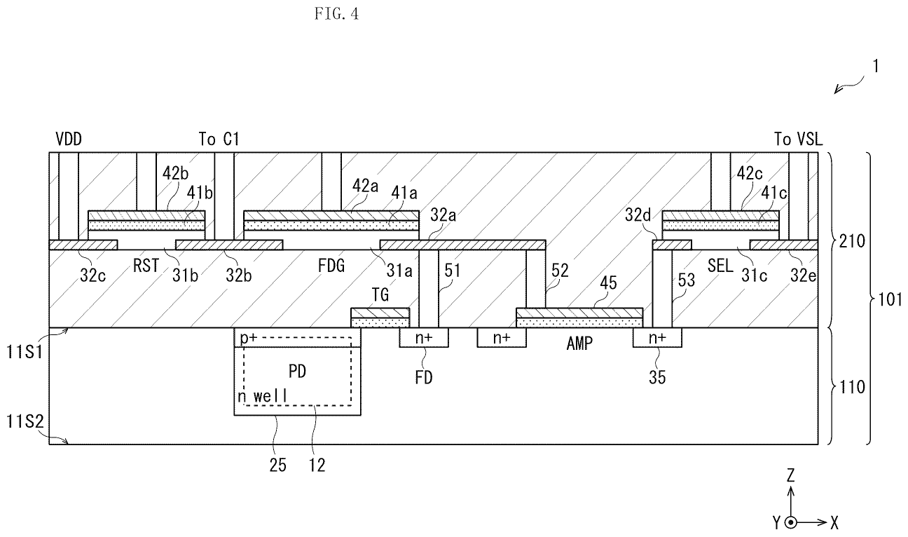

FIG. 4 is an explanatory diagram of an example of a cross-sectional configuration of the imaging device according to the first embodiment of the present disclosure. Each of the pixels P of the imaging device 1 has a configuration as illustrated in FIG. 4, for example. The imaging device 1 is implemented by a substrate 101 including a semiconductor layer 110 and a wiring layer 210. For example, the above-described photoelectric conversion section 12, readout circuit 20, and the like are formed in the substrate 101.

The semiconductor layer 110 is implemented by a semiconductor substrate such as a silicon (Si) substrate. It is to be noted that the semiconductor layer 110 may be implemented by a silicon on insulator (SOI) substrate, a silicon-germanium (SiGe) substrate, another compound semiconductor material, or the like.

As illustrated in FIG. 4, the semiconductor layer 110 includes a first surface 11S1 and a second surface 11S2 that are opposed to each other. The second surface 11S2 is a surface on a side opposite to the first surface 11S1. The first surface 11S1 of the semiconductor layer 110 is an element forming surface on which elements such as the transistors are formed. The first surface 11S1 of the semiconductor layer 110 is provided with gate electrodes, gate insulating films (e.g., gate oxide films), or the like. The second surface 11S2 of the semiconductor layer 110 is a light reception surface (light incident surface).

The semiconductor layer 110 is provided with the plurality of photoelectric conversion sections 12 (photoelectric conversion element) along the first surface 11S1 and the second surface 11S2 of the semiconductor layer 110. For example, the plurality of photoelectric conversion sections 12 is embedded in the semiconductor layer 110. The photoelectric conversion sections 12 are provided between the first surface 11S1 and the second surface 11S2 of the semiconductor layer 110.

As illustrated in FIG. 4, the semiconductor layer 110 has a well 25. For example, the well 25 is an n type semiconductor region and is an n type well (n well). In the example illustrated in FIG. 4, the semiconductor layer 110 is provided with the well 25 that is an n type well region. The photoelectric conversion section 12 includes a portion of the well 25.

The transfer transistor TG, the floating diffusion FD, and the like are provided on a side of the first surface 11S1 of the semiconductor layer 110. As illustrated in FIG. 4, for example, the floating diffusion FD includes an n+type semiconductor region.

For example, the wiring layer 210 includes an electrically conductive film and an insulating film, and also includes a plurality of wirings, vias, interlayer insulating films, and the like. The wirings of the wiring layer 210 are formed by using a metal material such as aluminum (Al), copper (Cu), or tungsten (W), for example. The wirings of the wiring layer 210 may be formed by using another electrically conductive material. The interlayer insulating film is formed by using, for example, silicon oxide (SiO), silicon nitride (SiN), silicon oxynitride (SiON), or the like.

The wiring layer 210 is provided with at least a portion of the above-described readout circuit 20. The wiring layer 210 has an element forming region where the respective transistors of the readout circuit 20 are formed. For example, a transistor of the readout circuit 20 is provided as a thin-film transistor (TFT) in the wiring layer 210.

In the imaging device 1, a portion or all of the transistors of the readout circuit 20 may be configured as the thin-film transistors and may be disposed in the wiring layer 210. For example, among the plurality of transistors of the readout circuit 20, some transistors may be disposed in the wiring layer 210, and other transistors may be disposed in the semiconductor layer 110.

In the example illustrated in FIG. 4, the transistor FDG, the reset transistor RST, and the selection transistor SEL are provided in the wiring layer 210 among the plurality of transistors of the readout circuit 20. In addition, the amplification transistor AMP is provided on the side of the first surface 11S1 of the semiconductor layer 110.

The transistor FDG includes a semiconductor region 31a, an electrode 32a, an electrode 32b, a gate insulating film 41a, and a gate electrode 42a. The reset transistor RST includes a semiconductor region 31b, an electrode 32b, an electrode 32c, a gate insulating film 41b, and a gate electrode 42b. The selection transistor SEL includes a semiconductor region 31c, an electrode 32d, an electrode 32e, a gate insulating film 41c, and a gate electrode 42c.

The wiring layer 210 has the semiconductor region 31a, the semiconductor region 31b, and the semiconductor region 31c that are provided on the insulating films (interlayer insulating films) serving as base films in the wiring layer 210. It can also be said that, the semiconductor region 31a, the semiconductor region 31b, and the semiconductor region 31c are disposed as substitute for a portion of the wiring layer 210.

The insulating films (interlayer insulating films) of the wiring layer 210 is formed by using TEOS, silicon nitride (SiN), silicon oxide (SiO), or the like, for example. Alternatively, for example, the insulating films of the wiring layer 210 may be formed by using SiCN, SiCON, HfO₂, Al₂O₃, ZrO₂, or the like. It is to be noted that the insulating films of the wiring layer 210 may be formed by using another insulating material. The insulating films of the wiring layer 21 also serve as passivation films (protection films) of the thin-film transistors, and are formed to surround the respective thin-film transistors.

Each of the semiconductor region 31a, the semiconductor region 31b, and the semiconductor region 31c is a region where a channel is formed (channel region). Each of the semiconductor region 31a, the semiconductor region 31b, and the semiconductor region 31c is formed by using a two-dimensional material (such as MoS₂, WS₂, MoSe₂, WSe₂, or HfS₂), oxide semiconductor (such as InGaZnO, InZnO, ZnO, SnO, or TiO₂), or the like.

It is to be noted that each of the semiconductor region 31a, the semiconductor region 31b, and the semiconductor region 31c may be formed by using an organic semiconductor (such as fullerene, pentacene, or rubrene), carbon nanotube, hydrogenated amorphous silicon, low-temperature polysilicon, or the like as a channel material.

The electrode 32a and the electrode 32b are a source electrode and a drain electrode of the transistor FDG. One of the electrodes 32a and 32b is the source electrode of the transistor FDG. Another of the electrodes 32a and 32b is the drain electrode of the transistor FDG.

In addition, the electrode 32b and the electrode 32c are a source electrode and a drain electrode of the reset transistor RST. One of the electrodes 32b and 32c is the source electrode of the reset transistor RST. Another of the electrodes 32b and 32c is the drain electrode of the reset transistor RST.

The electrode 32d and the electrode 32e are a source electrode and a drain electrode of the selection transistor SEL. One of the electrodes 32d and 32e is the source electrode of the selection transistor SEL. Another of the electrodes 32d and 32e is the drain electrode of the selection transistor SEL.

Each of the electrode 32a, the electrode 32b, the electrode 32c, the electrode 32d, and the electrode 32e is formed by using a metal material such as copper (Cu), tungsten (W), ruthenium (Ru), or cobalt (Co), for example. It is to be noted that the electrodes 32a, 32b, 32c, 32d, and 32e may be formed by using another electrically conductive material. The electrodes 32a to 32e may be implemented by an electrically conductive material of low resistance.

The electrode 32a of the transistor FDG is coupled to a via 51 (also referred to as contact) provided in the wiring layer 210 and is electrically coupled to the floating diffusion FD through the via 51. The electrode 32a of the transistor FDG is also coupled to a via 52 (contact) provided in the wiring layer 210 and is electrically coupled to a gate electrode 45 of the amplification transistor AMP through the via 52.

The electrode 32d of the selection transistor SEL is coupled to a via 53 (contact) provided in the wiring layer 210 and is electrically coupled to a semiconductor region 35 of the amplification transistor AMP through the via 53. For example, the semiconductor region 35 is an n+type semiconductor region formed by using n type impurities and is a source region of the amplification transistor AMP.

Each of the vias 51, 52, and 53 is formed by using a metal material such as gold (Au), platinum (Pt), palladium (Pd), copper (Cu), titanium (Ti), tungsten (W), titanium nitride (TiN), tantalum nitride (TaN), titanium aluminide (TiAl), bismuth (Bi), indium (In), aluminum (Al), scandium (Sc), cobalt (Co), or molybdenum (Mo), for example. It is to be noted that the vias 51, 52, and 53 may be formed by using another electrically conductive material.

Each of the gate insulating films 41a, 41b, and 41c is implemented by silicon oxide (SiO), silicon nitride (SiN), or the like, for example. Alternatively, for example, each of the gate insulating films 41a, 41b, and 41c is formed by using an insulating material such as Al₂O₃, HfO₂, ZrO₂, LaO₂, HfSiO, Y₂O₃, or SiON. It is to be noted that the gate insulating films 41a to 41c may be implemented by other insulating material.

Each of the gate electrodes 42a, 42b, and 42c is formed by using a metal material such as Au, Pt, Cu, Ti, W, Pd, TiN, TaN, TiAl, Bi, In, Al, Sc, Co, or Mo, for example. The gate electrodes 42a, 42b, and 42c may be formed by using another electrically conductive material. It is to be noted that vias (contacts) coupled to the respective gate electrodes 42a to 42c may be formed by using the same kinds of material as the vias 51 to 53.

As described above, the wiring layer 210 of the imaging device 1 according to the present embodiment is provided with at least some of the transistors of the pixels P. The transfer transistor TG, the amplification transistor AMP, the selection transistor SEL, the transistor FDG, the reset transistor RST, and the like are allocated to the different layers including the semiconductor layer 110 and the wiring layer 210. This allows the imaging device 1 to have the configuration that has an advantage in miniaturization.

According to the present embodiment, at least some transistors of the readout circuit 20 are provided as the thin-film transistors (TFTs) in the wiring layer 210. This makes it possible to reduce footprints of the respective transistors of the readout circuit 20. Therefore, it becomes possible to reserve a region for forming the photoelectric conversion section 12 and to improve its quantum efficiency.

In addition, it is also possible to increase the area of a region for disposing the transistors in the pixel P in comparison with a case where all the transistors of the pixel P are provided in the semiconductor layer. This makes it possible to increase the sizes of the transistors of the pixel P. It is possible to increase the areas (such as gate width or gate length) of transistors such as the amplification transistor AMP of the readout circuit 20, and to reduce noise mixed into the signal of the pixel.

It is possible to improve characteristics of the transistors of the readout circuit 20 (such as amplification transistor AMP, selection transistor SEL, transistor FDG, and reset transistor RST). Accordingly, it becomes possible to suppress deterioration in the quality of pixel signals. This makes it possible to suppress deterioration in image quality of images generated by using the pixel signals.

In addition, it is possible to reduce the number of steps in a manufacturing process and to prevent an increase in manufacturing cost of the imaging device 1 in comparison with a case where the transistors of the pixel P are stacked in such a manner that the transistors are allocated to different semiconductor substrates. It is also possible to prevent the semiconductor layer 110 including the photoelectric conversion section 12 from being subjected to unnecessary high-temperature treatment.

In addition, the imaging device 1 makes it possible to electrically couple transistors provided in the semiconductor layer 110 to transistors provided in the wiring layer 210 through wiring of the wiring layer 210. This makes it possible to improve degree of freedom of layout. This make it possible to prevent addition of unnecessary parasitic resistance or parasitic capacitance to signal paths in comparison with a case where the transistors of the pixel P are coupled via a through electrode that penetrates the semiconductor substrates. This makes it possible to suppress deterioration in signal quality.

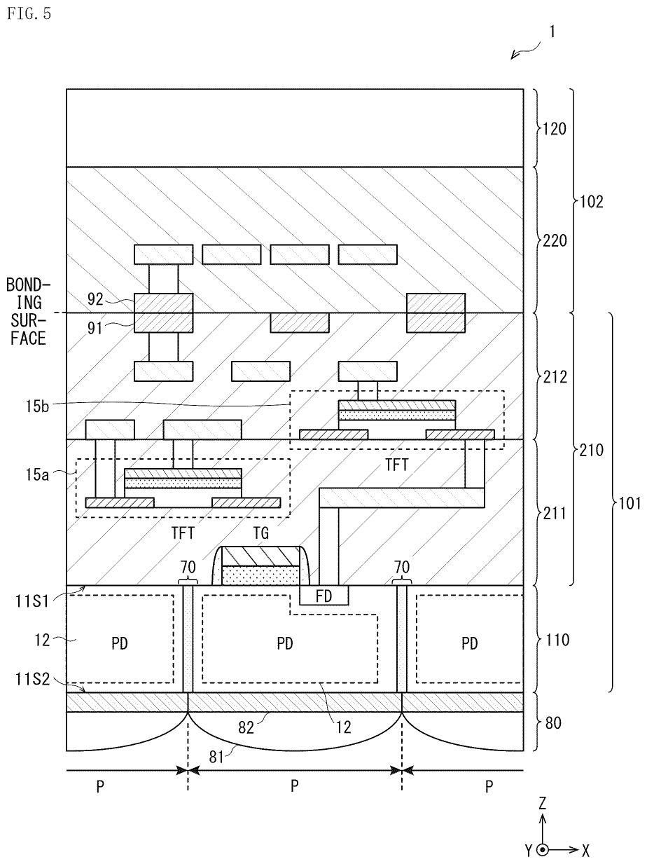

FIG. 5 is a diagram illustrating an example of a cross-sectional configuration of the imaging device according to the first embodiment. For example, as illustrated in FIG. 5, the imaging device 1 includes the substrate 101 and a substrate 102. The substrate 101 includes a light-guiding section 80, the semiconductor layer 110, and the wiring layer 210. The substrate 102 includes a semiconductor layer 120 and a wiring layer 220.

The imaging device 1 has a structure where the light-guiding section 80, the semiconductor layer 110, the wiring layer 210, the wiring layer 220, and the semiconductor layer 120 are stacked in the Z-axis direction. The light-guiding section 80, the semiconductor layer 110, the wiring layer 210, the wiring layer 220, and the semiconductor layer 120 are provided from a light incident side. The semiconductor layer 110 and the semiconductor layer 120 are implemented by respective semiconductor substrate (such as silicon substrate or SOI substrate, for example).

In the example illustrated in FIG. 5, the light-guiding section 80 is provided on a side of the second surface 11S2 of the semiconductor layer 110. The wiring layer 210 is provided on the side of the first surface 11S1 of the semiconductor layer 110. The light-guiding section 80 is provided on a side where light from the optical system enters, and the wiring layer 210 is provided on a side opposite to the light incident side. The imaging device 1 is a so-called back side illumination imaging device.

The wiring layer 210 is a multilayer wiring layer including a first wiring layer 211 and a second wiring layer 212. For example, each of the first wiring layer 211 and the second wiring layer 212 includes an electrically conductive film and an insulating film, and also includes a plurality of wirings, vias, interlayer insulating films, and the like. The wiring layer 210 (multilayer wiring layer) is provided with at least some transistors of the above-described readout circuit 20 as the thin-film transistors.

For example, the first wiring layer 211 is a wiring layer formed through middle-of-line (MOL). The first wiring layer 211 is a layer including a contact interlayer film and may also be referred to as an MOL layer (or MOL wiring layer). In addition, for example, the second wiring layer 212 is a wiring layer formed through back-end-of-line (BEOL) and may also be referred to as a BEOL layer (or BEOL wiring layer).

The light-guiding section 80 is stacked on the semiconductor layer 110 in a thickness direction orthogonal to the second surface 11S2 of the semiconductor layer 110. The light-guiding section 80 includes lenses 81 and filters 82, and guides incident light toward a side of the semiconductor layer 110. The photoelectric conversion section 12 photoelectrically converts the light incident through the lens 81 and the filter 82.

For example, the lens (lens section) 81 is provided on the side of the second surface 11S2 of the semiconductor layer 110 for each pixel P or for a plurality of pixels P. The lens 81 is an optical member that is also referred to as an on-chip lens. The lens 81 receives light incident from a subject through the optical system such as an imaging lens.

The filter 82 is configured to selectively transmit light of a specific wavelength band among the incident light. The filter 82 is a color filter (R, G, or B), a complementary color filter, a filter that transmits infrared light, or other filters, and is provided between the lens 81 and the semiconductor layer 110.

For example, the filter 82 is provided on the side of the second surface 11S2 of the semiconductor layer 110 for each pixel P or for a plurality of pixels P. It is to be noted that the filter 82 may be omitted from the imaging device 1 if necessary. The filter 82 does not have to be provided for some or all of the pixels P of the imaging device 1. For example, the filter 82 does not have to be provided for a pixel P that receives and photoelectrically converts white (W) light.

In addition, as illustrated in the example of FIG. 5, the imaging device 1 is provided with separation sections 70. The separation section 70 is provided between the adjacent photoelectric conversion sections 12 in the semiconductor layer 110 to separate the photoelectric conversion sections 12 from each other. The separation sections 70 are formed by using trenches (groove sections) provided at boundaries between the adjacent pixels P.

As an example, the separation sections 70 are provided to penetrate the semiconductor layer 110. For example, the separation sections 70 are provided to surround the respective photoelectric conversion sections 12 in the semiconductor layer 110. As an example, the inside of the trenches of the separation sections 70 is provided with an insulating film such as an oxide film (e.g., silicon dioxide film) or nitride film (e.g., silicon nitride film). It is to be noted that polysilicon, a metal material, or the like may be embedded in the trenches of the separation sections 70.

The separation sections 70 makes it possible to suppress leakage of the electric charge that is photoelectrically converted by the photoelectric conversion section 12 of a pixel P into surrounding pixels P. It is also possible to suppress leakage of light into the surrounding pixels P. It is to be noted that separation sections that form potential barrier may be disposed as the separation sections 70 between the plurality of adjacent photoelectric conversion sections 12 to electrically separate the adjacent photoelectric conversion sections 12 from each other.

For example, the wiring layer 220 includes an electrically conductive film and an insulating film, and also includes a plurality of wirings, vias, interlayer insulating films, and the like. The wiring layer 220 is a multilayer wiring layer and is stacked on the semiconductor layer 120. The wirings of the wiring layer 220 are formed by using a metal material such as aluminum, copper, or tungsten, for example. The wirings of the wiring layer 220 may be formed by using another electrically conductive material. The interlayer insulating films are formed by using an insulating material such as silicon oxide, silicon nitride, or silicon oxynitride, for example.

The second wiring layer 212 is provided with a plurality of electrodes 91. The wiring layer 220 is provided with a plurality of electrodes 92. The electrodes 91 and 92 are respective electrodes formed by using copper (Cu), for example. The electrodes 91 and 92 are electrodes to be used to join metal electrodes and may also be referred to as joint electrodes. As an example, the substrate 101 and the substrate 102 are bonded through so-called Cu—Cu bonding that is bonding between the metal electrodes (electrodes 91 and 92) implemented by Cu.

The circuits of the substrate 101 and the circuits of the substrate 102 are electrically coupled through the electrode 91 and the electrode 92. For example, the semiconductor layer 120 and the wiring layer 220 are provided with the above-described signal processing section 112 including the AD conversion sections 40. The semiconductor layer 120 and the wiring layer 220 may also be provided with the pixel drive section 111, the control section 113, the processing section 114, and the like. The semiconductor layer 120 and the wiring layer 220 may be provided with other circuits such as memory, processor, power supply circuit, or interface circuit.

It is to be noted that the electrode 91 of the second wiring layer 212 and the electrode 92 of the wiring layer 220 may be implemented by a metal material other than copper, such as nickel (Ni), cobalt (Co), or gold (Au), for example. Alternatively, a bump may be used to stack the substrate 101 and the substrate 102.

At least some transistors of the readout circuit 20 are provided as the thin-film transistors (TFTs) in the wiring layer 210 of the imaging device 1. The transistors of the readout circuit 20 may be allocated to the different wiring layers including the first wiring layer 211 (MOL layer) and the second wiring layer 212 (BEOL layer). In the example illustrated in FIG. 5, the first wiring layer 211 is provided with a pixel transistor 15a, and the second wiring layer 212 is provided with a pixel transistor 15b. Each of the pixel transistors 15a and 15b may be configured as a thin-film transistor.

The imaging device 1 includes a plurality of pixel transistors 15a and a plurality of pixel transistors 15b that are provided for each pixel P or for a plurality of pixels P. Each of the pixel transistors 15a and 15b is the above-described transistor of the readout circuit 20. The pixel transistors 15a and 15b are used as the amplification transistor AMP, the selection transistor SEL, the transistor FDG, the reset transistor RST, or the like.

The pixel transistor 15a is positioned in the first wiring layer 211 and is provided in a tier different from that of the transfer transistor TG. In addition, the pixel transistor 15b is positioned in the second wiring layer 212 and is provided in a tier different from that of the transfer transistor TG or the pixel transistor 15a. It may be said that the pixel transistor15b is provided in an upper part of the wiring layer 210 serving as the multilayer wiring layer, and the pixel transistor15a is provided in a lower part of the wiring layer 210.

As an example, each of the transistors such as the amplification transistor AMP, the selection transistor SEL, the transistor FDG, or the reset transistor RST of the readout circuit 20 may be allocated as the pixel transistor 15a of the first wiring layer 211 or the pixel transistor 15b of the second wiring layer 212, and is shared by the plurality of pixels P.

It is to be noted that the transistors of the readout circuit 20 may be allocated to only one of the first wiring layer 211 (MOL layer) or the second wiring layer 212 (BEOL layer). Among the amplification transistor AMP, the selection transistor SEL, the transistor FDG, the reset transistor RST, and the like of the readout circuit 20, at least some of the transistors may be disposed only in the first wiring layer 211 or only in the second wiring layer 212.

Each of the pixel transistors 15a and 15b may have a planar (Planer) structure or a three-dimensional structure. In the example illustrated in FIG. 5, each of the pixel transistors 15a and 15b is a planar transistor. Each of the pixel transistors 15a and 15b may be a vertical transistor.

As described above, according to the present embodiment, at least some of the transistors of the readout circuit 20 is disposed in the wiring layer 210. For example, the transistors of the readout circuit 20 are disposed in the first wiring layer 211 and the second wiring layer 212 as the pixel transistors 15a or the pixel transistors 15b. This allows the imaging device 1 to have the configuration that has an advantage in miniaturization of the pixels. It is possible to achieve the high-performance imaging device 1 while avoiding increase in footprints of the transistors of the pixels.

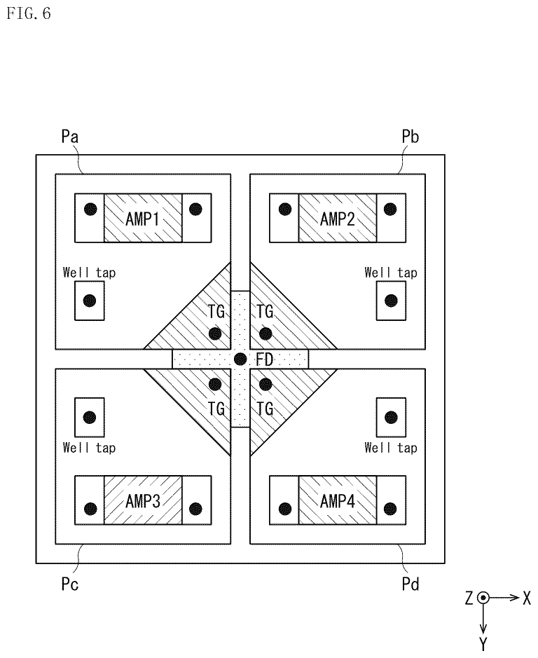

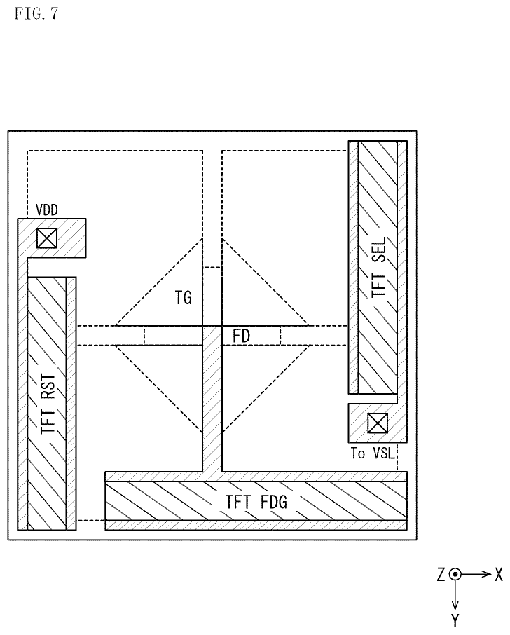

FIG. 6 and FIG. 7 are explanatory diagrams of examples of planar configurations of the imaging device according to the first embodiment. FIG. 6 illustrates an example of a planar configuration of the side of the first surface 11S1 of the semiconductor layer 110 of the imaging device 1. FIG. 7 illustrates an example of a planar configuration of the wiring layer 210 of the imaging device 1.

As illustrated in the examples of FIG. 6 and FIG. 7, among the plurality of transistors of the readout circuit 20, the amplification transistor AMP may be disposed on the side of the first surface 11S1 of the semiconductor layer 110, and the transistor FDG, the reset transistor RST, and the selection transistor SEL may be disposed in the wiring layer 210 as the thin-film transistors (TFTs). In this case, it is possible to sufficiently increase the area where the amplification transistor AMP is disposed.

As illustrated in the example of FIG. 6, it is also possible to provide a plurality of amplification transistors AMP (amplification transistor AMP1, amplification transistor AMP2, amplification transistor AMP3, and amplification transistor AMP4 in FIG. 6) that are coupled side by side to each other. The readout circuit 20 may generate a pixel signal by using the amplification transistors AMP1 to AMP4 that are coupled side by side to each other and may output it to the signal line VSL through the selection transistor SEL of the wiring layer 210. This makes it possible to reduce noise mixed into the pixel signal.

As described above with reference to FIG. 5, the transistor FDG, the reset transistor RST, and the selection transistor SEL of the readout circuit 20 may be allocated to the plurality of wiring layers including the first wiring layer 211 and the second wiring layer 212, for example.

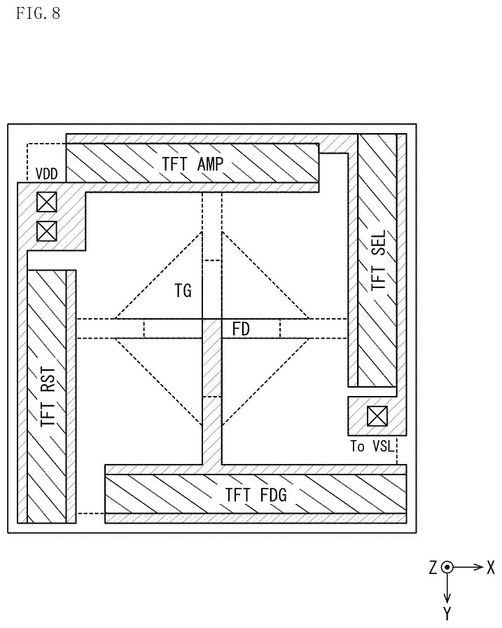

It is to be noted that layout positions, shapes, and the like of the respective transistors of the readout circuit 20 are not limited to those described in the above example, but may be modified appropriately. For example, as illustrated in FIG. 8, the amplification transistor AMP, the transistor FDG, the reset transistor RST, and the selection transistor SEL may be provided in the wiring layer 210.

### Workings and Effects

The light detecting device according to the present embodiment includes: the first substrate (substrate 101) including the photoelectric conversion element (photoelectric conversion section 12) that photoelectrically converts light and the readout circuit (readout circuit 20) configured to output a first signal based on electric charge converted by the photoelectric conversion element; and the second substrate (substrate 102) that is stacked on the first substrate and that includes the signal processing circuit (e.g., signal processing section 112) configured to execute signal processing on the first signal. The first substrate includes the semiconductor layer (semiconductor layer 110) and the wiring layer (wiring layer 210). The readout circuit includes a first transistor (e.g., the amplification transistor AMP, the selection transistor SEL, the transistor FDG, or the reset transistor RST) provided in the wiring layer.

At least some transistors of the readout circuit 20 are provided in the wiring layer 210 of the light detecting device (imaging device 1) according to the present embodiment. This allows the imaging device 1 to have the configuration that has an advantage in miniaturization of the pixels. This makes it possible to achieve the light detecting device having an advantage in miniaturization.

Next, modification examples of the present disclosure will be described. Hereinafter, structural elements that are similar to the above-described embodiment will be denoted with the same reference signs as the above-described embodiment, and repeated description will be omitted appropriately.

### 2. Modification Examples

### (2-1. Modification Example 1)

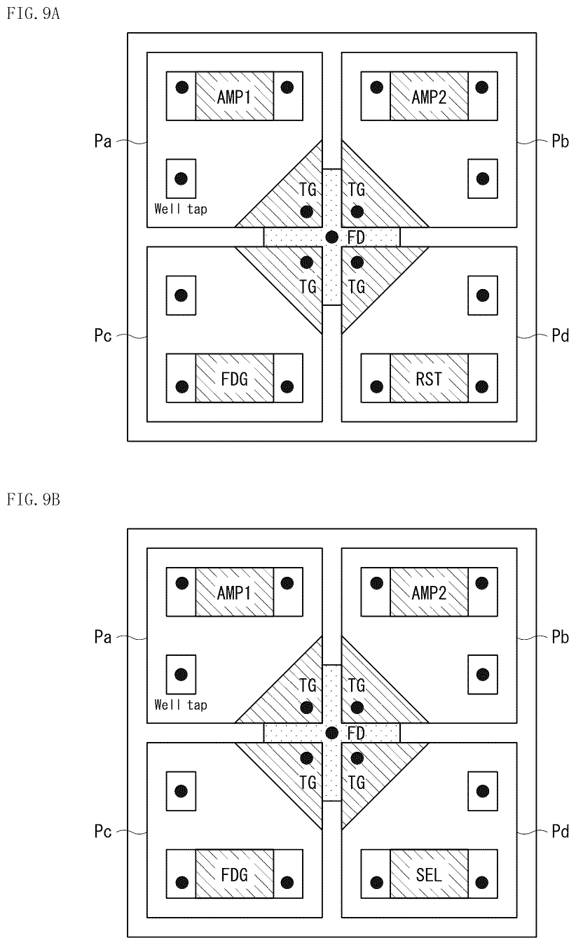

In the above-described embodiment, the examples of arrangement of the transistors of the pixels P have been described. However, the arrangement of the transistors of the pixels P is not limited to the above-described examples. FIG. 9A and FIG. 9B are explanatory diagrams of configuration examples of an imaging device according to Modification Example 1 of the present disclosure. As illustrated in the example of FIG. 9A or FIG. 9B, the readout circuit 20 may include two amplification transistors AMP (amplification transistor AMP1 and amplification transistor AMP2 in FIG. 9A and FIG. 9B) that are coupled side by side to each other.

The amplification transistor AMP1 and the amplification transistor AMP2 make it possible to generate and output a pixel signal. This makes it possible to reduce noise mixed into the pixel signal. It is to be noted that, as illustrated in FIG. 9A, the transistor FDG and the reset transistor RST may be disposed in the semiconductor layer 110, and the selection transistor SEL may be disposed in the wiring layer 210. Alternatively, for example, as illustrated in FIG. 9B the transistor FDG and the selection transistor SEL may be disposed in the semiconductor layer 110, and the reset transistor RST may be disposed in the wiring layer 210.

### (2-2. Modification Example 2)

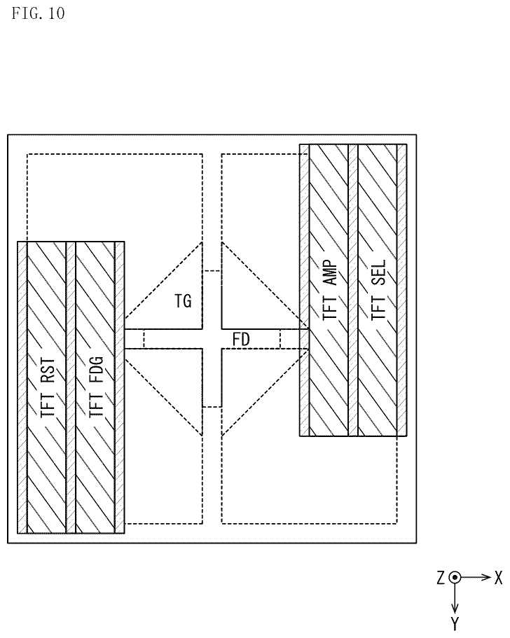

FIG. 10 is an explanatory diagram of the configuration example of an imaging device according to Modification Example 2. The plurality of thin-film transistors of the wiring layer 210 may be configured to share an electrode (source electrode or drain electrode).

As illustrated in an example of FIG. 10, source electrodes (or drain electrodes) of the transistor FDG and the reset transistor RST may be integrated, for example. In addition, source electrodes (or drain electrodes) of the amplification transistor AMP and the selection transistor SEL may be integrated. This makes it possible to suppress an increase in the sizes of the pixels.

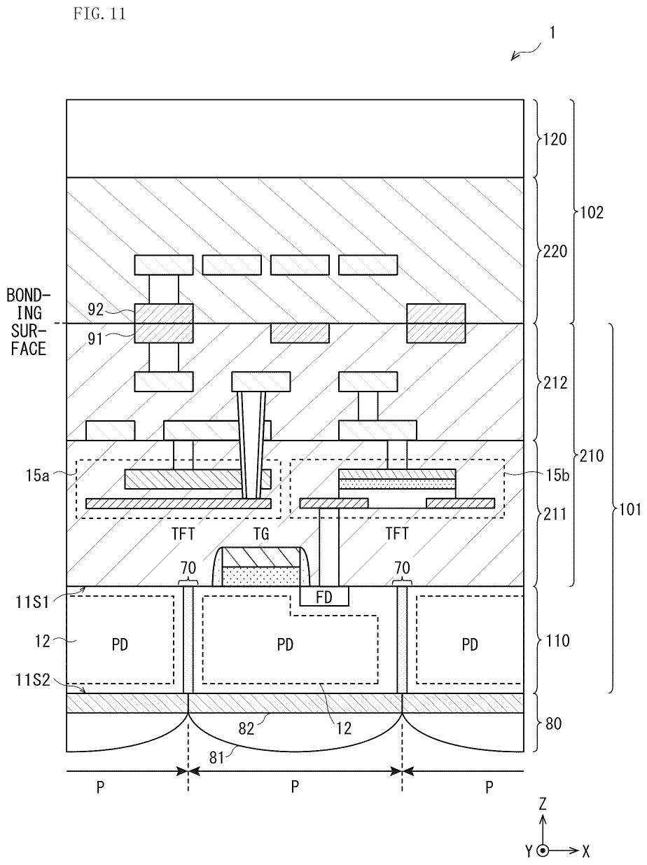

As illustrated in a schematic example of FIG. 11, the thin-film transistor (pixel transistor 15a in FIG. 11) of the imaging device 1 may be the vertical transistor. For example, the thin-film transistor may be a gate-all-around (GAA) TFT having a structure where a gate surrounds the channel region.

For example, the thin-film transistor may be a channel-all-around (CAA) TFT having a structure where the channel region surrounds the gate electrode. By configuring a transistor of the readout circuit 20 as the vertical transistor, it becomes possible to further reduce the footprint of the transistor.

### (2-3. Modification Example 3)

In the above-described embodiment, the example of the imaging device 1 having a stacked structure where the substrate 101 and the substrate 102 are stacked has been described. However, the photoelectric conversion sections 12 of the respective pixels P, the readout circuit 20, the pixel drive section 111, the signal processing section 112, and the like may be provided in one substrate. For example, the pixel section 100, the pixel drive section 111, the signal processing section 112, and the like may be provided in the substrate 101 including the semiconductor layer 110 and the wiring layer 210.

### 2. Second Embodiment

Next, a second embodiment of the present disclosure will be described. Hereinafter, structural elements that are similar to the above-described embodiment will be denoted with the same reference signs as the above-described embodiment, and repeated description will be omitted appropriately.

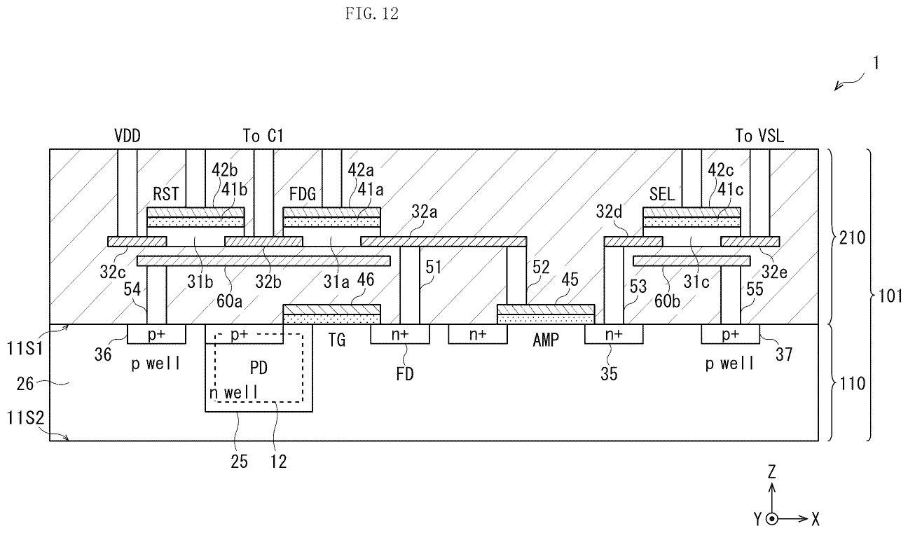

FIG. 12 is an explanatory diagram of an example of a cross-sectional configuration of an imaging device according to a second embodiment of the present disclosure. The imaging device 1 includes a plurality of electric conductors 60 (electric conductor 60a and electric conductor 60b in FIG. 12). As illustrated in the example of FIG. 12, the imaging device 1 may include the electric conductors 60 provided around transistors disposed in the wiring layer 210.

In the imaging device 1, at least some of the transistors of the pixels P are provided in the wiring layer 210. In the example illustrated in FIG. 12, the transistor FDG, the reset transistor RST, and the selection transistor SEL are provided in the wiring layer 210 among the plurality of transistors of the readout circuit 20. The amplification transistor AMP is provided on the side of the first surface 11S1 of the semiconductor layer 110. In addition, the transfer transistor TG is provided on the side of the first surface 11S1 of the semiconductor layer 110.

For example, the wiring layer 210 includes the transistors of the pixel P provided as the thin-film transistors (TFTs) stacked on the electric conductors 60. The electric conductors 60 are supplied with a predetermined potential (voltage) through the wirings, vias, or the likes of the wiring layer 210, for example. The electric conductors 60 are shield sections and may be referred to as shield regions (or shield layers).

For example, the electric conductors 60 are provided below the channel regions of the transistors in the wiring layer 210. The electric conductors 60 are disposed along and below the channel regions of the transistors. For example, the electric conductors 60 extend in the X-axis direction and the Y-axis direction to cover the channel regions of the transistors of the wiring layer 210 from the side of the semiconductor layer 110.

The electric conductors 60 (electric conductors 60a and 60b in FIG. 12) are implemented by polysilicon (Poly-Si), a semiconductor material doped with impurities, a metal material, or the like. For example, the electric conductors 60 may be implemented by polysilicon including phosphorus (P), arsenic (As), or boron (B) as impurities. The electric conductors 60 may be implemented by silicon that is partially (e.g., surface side) or completely silicided by using titanium (Ti), cobalt (Co), nickel (Ni), platinum (Pt), or the like.

Alternatively, for example, the electric conductors 60 may be formed by using a metal material such as tungsten (W), titanium (Ti), titanium nitride (TiN), tantalum nitride (TaN), copper (Cu), aluminum (Al), cobalt (Co), or nickel (Ni). The electric conductors 60 may be formed by using another electrically conductive material.

In the example illustrated in FIG. 12, the electric conductor 60a is provided with respect to the transistor FDG and the reset transistor RST of the readout circuit 20. The transistor FDG and the reset transistor RST are stacked with respect to the electric conductor 60a in the wiring layer 210.

For example, as illustrated in the example of FIG. 12, the electric conductor 60a is formed below the semiconductor region 31a and the semiconductor region 31b. The semiconductor region 31a serves as a channel region of the transistor FDG. The semiconductor region 31b serves as a channel region of the reset transistor RST. A portion of the electric conductor 60a is positioned below the semiconductor region 31a, and another portion of the electric conductor 60a is positioned below the semiconductor region 31b.

In the example illustrated in FIG. 12, the electric conductor 60a is disposed between the transistor FDG (or reset transistor RST) and the transfer transistor TG that is provided on the side of the first surface 11S1 of the semiconductor layer 110. As an example, as illustrated in FIG. 12, the electric conductor 60a is formed between the transistor FDG (or reset transistor RST) and the transfer transistor TG in such a manner that the electric conductor 60a covers bottoms (bases) of the respective semiconductor regions 31a and 31b.

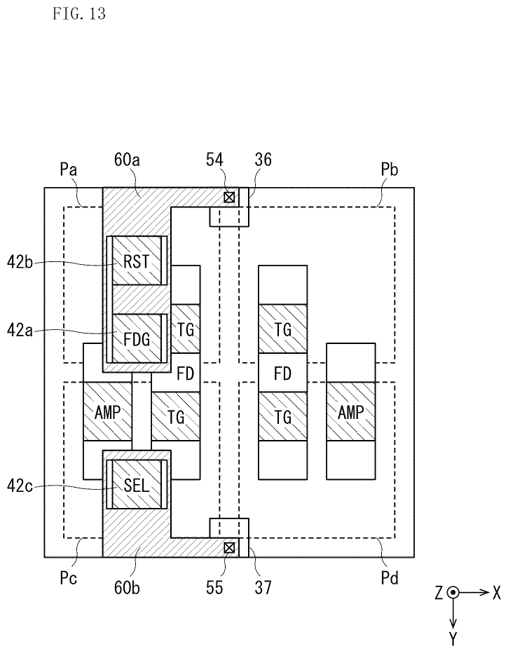

FIG. 13 is an explanatory diagram of an example of a planar configuration of the imaging device according to the second embodiment. For example, as illustrated in FIG. 12 or FIG. 13, the electric conductor 60a is provided across the entire reset transistor RST and the entire transistor FDG, and extends in the X-axis direction and the Y-axis direction. The size (width, area, or the like) of the electric conductor 60a is larger than the sizes of the semiconductor regions 31a and 31b.

As illustrated in the example of FIG. 12, the electric conductor 60b is provided with respect to the selection transistor SEL. The selection transistor SEL is stacked with respect to the electric conductor 60b in the wiring layer 210. For example, the electric conductor 60b is formed along and below the semiconductor region 31c serving as a channel region of the selection transistor SEL.

The electric conductor 60b may be disposed between the selection transistor SEL and the amplification transistor AMP that is provided on the side of the first surface 11S1 of the semiconductor layer 110. As an example, the electric conductor 60b is formed between the selection transistor SEL and the amplification transistor AMP in such a manner that the electric conductor 60b covers the bottom (base) of the semiconductor region 31c.

In addition, for example, as illustrated in FIG. 12 or FIG. 13, the electric conductor 60b is provided across the entire selection transistor SEL, and extends in the X-axis direction and the Y-axis direction. The size (width, area, or the like) of the electric conductor 60b is larger than the sizes of the semiconductor region 31c.

For example, as illustrated in FIG. 13, the transistor FDG and the reset transistor RST include the respective gate electrodes 42a and 42b overlapping the electric conductor 60a. The electric conductor 60a and the gate electrode 42a of the transistor FDG are opposed to each other with the semiconductor region 31a interposed therebetween. The electric conductor 60a and the gate electrode 42b of the reset transistor RST are opposed to each other with the semiconductor region 31b interposed therebetween.

In addition, for example, as illustrated in FIG. 13, the selection transistor SEL includes the gate electrodes 42c overlapping a portion of the electric conductor 60b. The electric conductor 60b and the gate electrode 42c of the selection transistor SEL are opposed to each other with the semiconductor region 31c interposed therebetween.

In the example illustrated in FIG. 13, the size of the electric conductor 60a is larger than the size of the gate electrode 42a of the transistor FDG and the size of the gate electrode 42b of the reset transistor RST. In addition, the size of the electric conductor 60b is larger than the size of the gate electrode 42c of the selection transistor SEL.

The electric conductors 60 are supplied with a predetermined potential (voltage) through the wirings, vias, or the likes of the wiring layer 210, for example. The electric conductors 60 are shield members that may be electrically coupled to wiring or the like supplied with a certain amount of voltage. In the example illustrated in FIG. 12, the electric conductor 60a is coupled to a via 54 (contact) provided in the wiring layer 210 and is electrically coupled to a semiconductor region 36 through the via 54.

The electric conductor 60b is coupled to a via 55 (contact) provided in the wiring layer 210 and is electrically coupled to a semiconductor region 37 through the via 55. The via 54 and the via 55 are formed by using the same kinds of material as the vias 51 to 53, for example. The semiconductor region 36 and the semiconductor region 37 are provided in a well 26 of the semiconductor layer 110.

For example, the well 26 is a p type semiconductor region and is a p type well (p well). The semiconductor layer 110 of the imaging device 1 is provided with the well 26 that is a p type well region. The semiconductor region 36 and the semiconductor region 37 are respective semiconductor regions of the same electrical conductivity type as the well 26 and are provided on the side of the first surface 11S1 of the semiconductor layer 110. The semiconductor region 36 and the semiconductor region 37 are provided in the well 26 and are electrically coupled to the well 26.

In the example illustrated in FIG. 12, the semiconductor region 36 and the semiconductor region 37 are p+ type semiconductor regions formed by using p type impurities. The semiconductor regions 36 and 37 have respective impurity concentrations that are higher than that of the well 26, for example. For example, the semiconductor regions 36 and 37 are provided for each pixel P or for a plurality of pixels P.

The semiconductor region 36, the semiconductor region 37, and the well 26 are supplied with a reference potential such as a ground potential (GND potential) through the wirings, vias, or the like of the wiring layer 210. As an example, the semiconductor region 36, the semiconductor region 37, and the well 26 are supplied with a voltage VSS (e.g., 0 V) as the ground potential. The semiconductor regions 36 and 37 may be referred to as well contact regions. The vias 54 and 55 may be referred to as well contacts or well taps.

For example, the electric conductor 60a is electrically coupled to the via 54 and the semiconductor region 36, and is supplied with the ground potential (GND potential). In addition, the electric conductor 60b is electrically coupled to the via 55 and the semiconductor region 37, and is supplied with the ground potential. It is to be noted that the electric conductor 60a and the electric conductor 60b may be supplied with potentials that are different from the ground potential. The imaging device 1 according to the present embodiment includes the electric conductors 60, and this makes it possible to suppress crosstalk.

In a case where the imaging device 1 does not include the electric conductor 60, there is a possibility that the crosstalk may increase between the transistors of the semiconductor layer or the wirings of the wiring layer and the transistors of the wiring layer. For example, there is a possibility that a change (transition) in a potential of a gate electrode provided on the side of the first surface 11S1 of the semiconductor layer 110, a change in a potential of wiring provided on a lower side of the wiring layer 210, or another change may adversely affect the channel regions of the transistors of the wiring layer 210. In this case, for example, noise may be mixed into a pixel signal, and this may deteriorate the quality of the pixel signal. It is also considered that this brings about design constraints on the layout of the transistors.

Therefore, as described above, the imaging device 1 according to the present embodiment is provided with the electric conductors 60. The wiring layer 210 is provided with the electric conductors 60 corresponding to the transistors of the pixels P. This makes it possible to suppress crosstalk and to reduce noise mixed into the pixel signal. By using the electric conductors 60, it becomes possible to improve freedom of design of the transistors and the like. This makes it possible to prevent an increase in the sizes of the pixels due to the design constraints on the layout of the transistors.

The imaging device 1 includes the electric conductor 60a or the electric conductor 60b corresponding to the transistors (such as transistor FDG, reset transistor RST, or selection transistor SEL) provided in the wiring layer 210. This makes it possible to reduce the adverse effect on the transistors of the wiring layer 210. For example, variation in a potential of a gate electrode 46 or 45 makes it possible to reduce the adverse effect on the transistor FDG, the reset transistor RST, the selection transistor SEL, or the like. This makes it possible to achieve stable operation of the transistors.

### Workings and Effects

The light detecting device according to the present embodiment includes: the first substrate (substrate 101) including the photoelectric conversion element (photoelectric conversion section 12) that photoelectrically converts light and the readout circuit (readout circuit 20) configured to output a first signal based on electric charge converted by the photoelectric conversion element; and the second substrate (substrate 102) that is stacked on the first substrate and that includes the signal processing circuit (e.g., signal processing section 112) configured to execute signal processing on the first signal. The first substrate includes the semiconductor layer (semiconductor layer 110) and the wiring layer (wiring layer 210). The readout circuit includes the first transistor provided in the wiring layer. The wiring layer includes the electric conductor (electric conductors 60) provided between the semiconductor layer and the first transistor. The first transistor is provided to be stacked with respect to the electric conductor.

The light detecting device (imaging device 1) according to the present embodiment includes the electric conductors 60 (e.g., electric conductor 60a and electric conductor 60b) provided between the semiconductor layer 110 and the transistors (e.g., selection transistor SEL, transistor FDG, and reset transistor RST) of the readout circuit 20. This makes it possible to suppress generation of the crosstalk. Therefore, it becomes possible to achieve the light detecting device having an advantage in miniaturization.

### 4. Modification Examples

### (4-1. Modification Example 4)

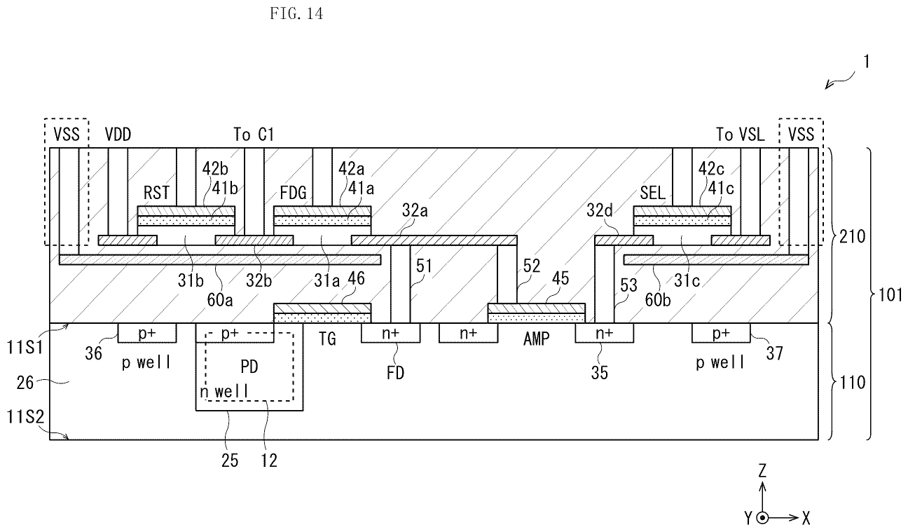

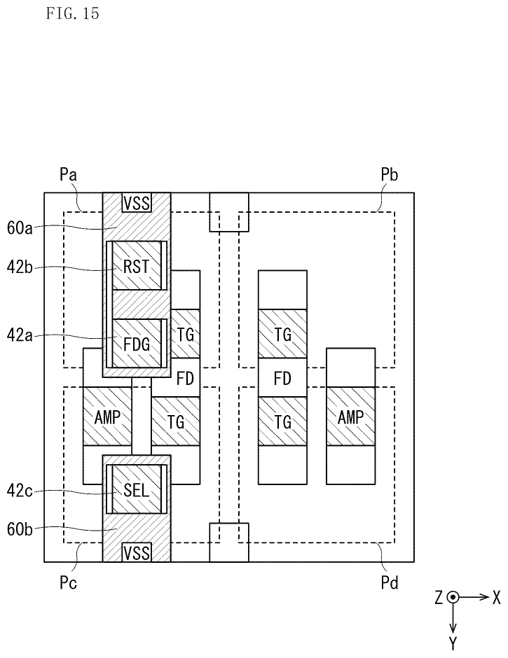

FIG. 14 and FIG. 15 are explanatory diagrams of a configuration example of an imaging device according to Modification Example 4 of the present disclosure. As indicated by dashed boxes in FIG. 14, the electric conductors 60 may be electrically coupled to wirings, vias, or the like supplied with predetermined potentials. For example, the wiring layer 210 may include the electric conductors 60a and 60b that are electrically coupled to an earthing wire (ground wire).

In the example illustrated in FIG. 14 or FIG. 15, the electric conductor 60a is electrically coupled to wiring, via, or the like supplied with the voltage VSS (e.g., 0 V) as the ground potential, and is supplied with the voltage VSS. In addition, the electric conductor 60b is electrically coupled to wiring, via, or the like supplied with the voltage VSS, and is supplied with the Voltage VSS.

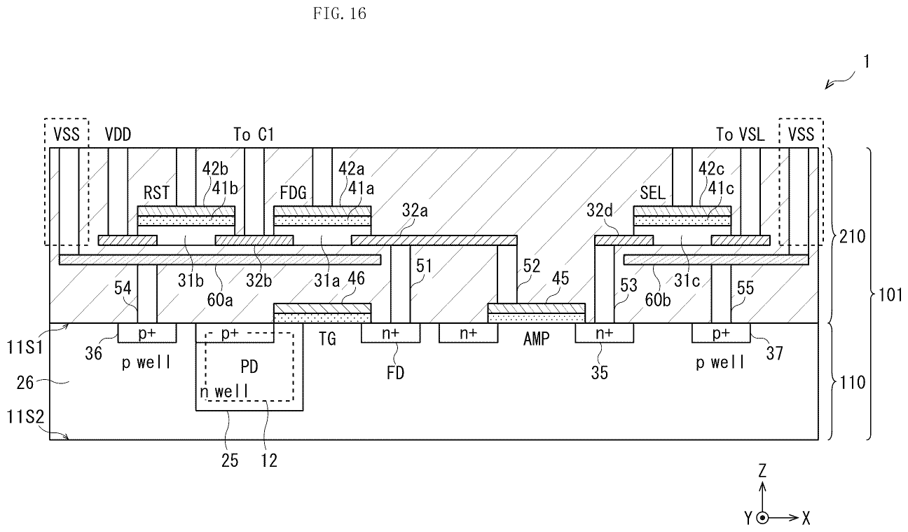

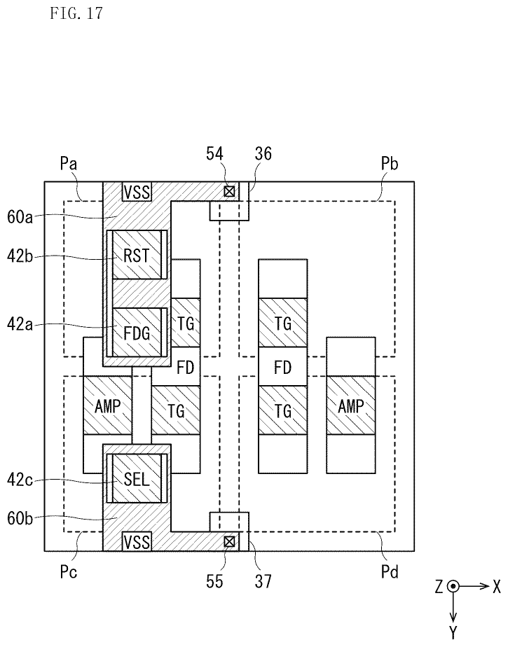

FIG. 16 and FIG. 17 are explanatory diagrams of another configuration example of the imaging device according to Modification Example 4. As illustrated in the example of FIG. 16 or FIG. 17, the electric conductor 60a may be electrically coupled to the semiconductor region 36 disposed in the well 26 and to wiring supplied with the voltage VSS. In addition, the electric conductor 60b may be electrically coupled to the semiconductor region 37 disposed in the well 26 and to wiring supplied with the voltage VSS.

In the case of using the imaging device 1 according to the present modification, it is also possible to suppress the crosstalk and to suppress deterioration in quality of the pixel signals. According to the present modification, it is also possible to achieve effects that are similar to the above-described embodiments. It is to be noted that the imaging device 1 may include only one of the electric conductor 60a or the electric conductor 60b.

### (4-2. Modification Example 5)

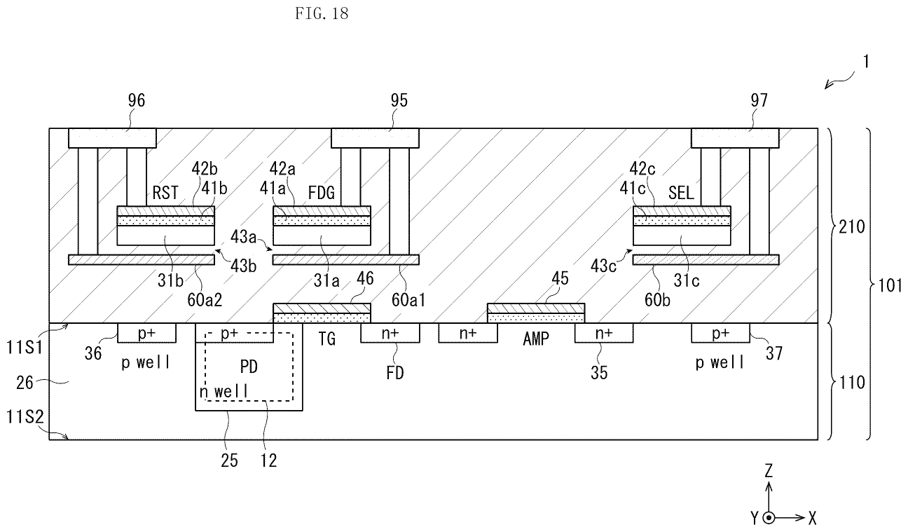

FIG. 18 is an explanatory diagram of a configuration example of an imaging device according to Modification Example 5. The imaging device 1 may be configured to control a voltage to be supplied to the electric conductors 60. The electric conductors 60 provided for transistors in the wiring layer 210 may be electrically coupled to gate electrodes of the respective transistors.

For example, the imaging device 1 may utilize the insulating film (interlayer insulating film) of the wiring layer 210 as the gate insulating film below the channel regions, and may be provided with the electric conductors 60 as back gate electrodes. Therefore, it is possible to use the electric conductors 60 as the back gate electrodes, and this allows the transistors of the wiring layer 210 to have a double-gate structure.

For example, as illustrated in the example of FIG. 18, the imaging device 1 may include an electric conductor 60a1, an electric conductor 60a2, and an electric conductor 60b. The electric conductor 60a1 is provided for the transistor FDG. The electric conductor 60a2 is provided for the reset transistor RST. In addition, the electric conductor 60b is provided with respect to the selection transistor SEL.

In the example illustrated in FIG. 18, a gate insulating film 43a is provided below a channel region (semiconductor region 31a) of the transistor FDG. For example, the gate insulating film 43a is implemented by an insulating film of the wiring layer 210, and is formed between the semiconductor region 31a and the electric conductor 60a1. The electric conductor 60a1 is provided below the gate insulating film 43a.

The transistor FDG may include the gate insulating film 43a and the electric conductor 60a1 serving as a back gate, and may have the double-gate structure. For example, as illustrated in the example of FIG. 18, the electric conductor 60a1 is electrically coupled to the gate electrode 42a of the transistor FDG through wiring 95 of the wiring layer 210. ON/OFF control is performed on the transistor FDG by a signal voltage supplied to the wiring 95.

In addition, in the example illustrated in FIG. 18, a gate insulating film 43b is provided below a channel region (semiconductor region 31b) of the reset transistor RST. For example, the gate insulating film 43b is implemented by the insulating film of the wiring layer 210, and is formed between the semiconductor region 31b and the electric conductor 60a2. The electric conductor 60a2 is provided below the gate insulating film 43b.

The reset transistor RST may include the gate insulating film 43b and the electric conductor 60a2 serving as a back gate, and may have the double-gate structure. For example, as illustrated in the example of FIG. 18, the electric conductor 60a2 is electrically coupled to the gate electrode 42b of the reset transistor RST through wiring 96 of the wiring layer 210. ON/OFF control is performed on the reset transistor RST by a signal voltage supplied to the wiring 96.

In addition, a gate insulating film 43c is provided below a channel region (semiconductor region 31c) of the selection transistor SEL. For example, the gate insulating film 43c is implemented by the insulating film of the wiring layer 210, and is formed between the semiconductor region 31c and the electric conductor 60b. The electric conductor 60b is provided below the gate insulating film 43c.

The selection transistor SEL may include the gate insulating film 43c and the electric conductor 60b serving as a back gate, and may have the double-gate structure. For example, as illustrated in the example of FIG. 18, the electric conductor 60b is electrically coupled to the gate electrode 42c of the selection transistor SEL through wiring 97 of the wiring layer 210. ON/OFF control is performed on the selection transistor SEL by a signal voltage supplied to the wiring 97.

For example, the gate insulating films 43a to 43c may be formed by using the same material as the gate insulating films 41a to 41c. For example, the gate insulating film 43a may have a film thickness (thickness in the Z-axis direction) that is substantially the same as the film thickness of the gate insulating film 41a. Also, the gate insulating film 43a may have a film thickness within a range of one time or more and two times or less the film thickness of the gate insulating film 41a.

For example, the gate insulating film 43b may have a film thickness that is substantially the same as the film thickness of the gate insulating film 41b. Also, the gate insulating film 43b may have a film thickness (thickness) within a range of one time or more and two times or less the film thickness of the gate insulating film 41b. For example, the gate insulating film 43c may have a film thickness that is substantially the same as the film thickness of the gate insulating film 41c. Also, for example, the gate insulating film 43c may have a film thickness within a range of one time or more and two times or less the film thickness of the gate insulating film 41c.

It is possible for the transistors of the wiring layer 210 of the imaging device 1 according to the present modification to have the double gate structures. This makes it possible to improve characteristics of the transistors. This makes it possible to improve short-channel characteristics of the transistors of the pixels P provided in the wiring layer 210, and to suppress drain-induced barrier lowering. It is also possible to suppress leakage current and improve ON/OFF ratios of the transistors.

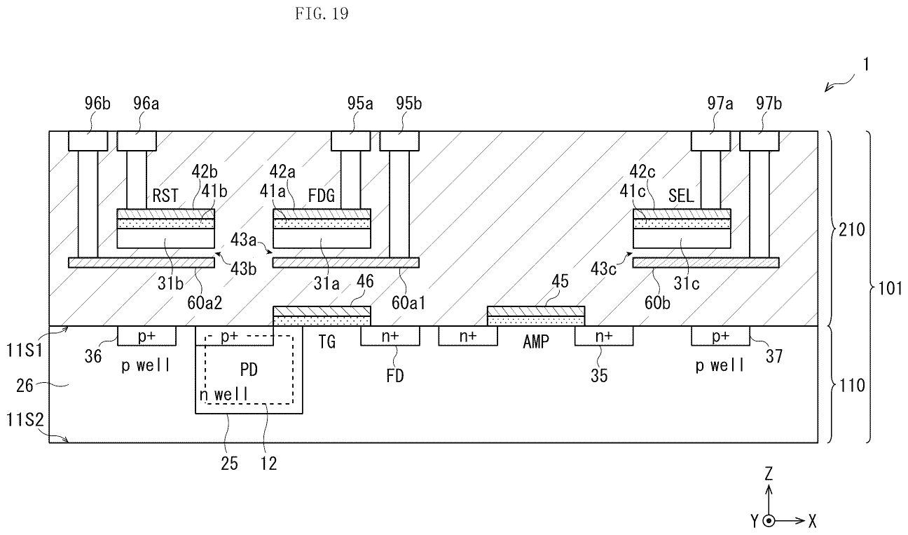

FIG. 19 is an explanatory diagram of another configuration example of an imaging device according to Modification Example 5. The gate electrodes of the transistors (thin-film transistors) in the wiring layer 210 may be electrically coupled to wirings, vias, or the like that are different from those of the electric conductors 60 serving as the back gates. This makes it possible to independently (individually) control voltages of the gate electrodes and voltages of back gate electrodes.

In the example illustrated in FIG. 19, the gate electrode 42a of the transistor FDG is electrically coupled to wiring 95a, and the electric conductor 60a1 is electrically coupled to wiring 95b. The gate electrode 42b of the reset transistor RST is electrically coupled to wiring 96a, and the electric conductor 60a2 is electrically coupled to wiring 96b. In addition, the gate electrode 42c of the selection transistor SEL is electrically coupled to wiring 97a, and the electric conductor 60b is electrically coupled to wiring 97b.

For example, the gate insulating film 43b may have a film thickness that is substantially the same as the film thickness of the gate insulating film 41b. Also, the gate insulating film 43b may have a film thickness within a range of one time or more and four times or less the film thickness of the gate insulating film 41b. For example, the gate insulating film 43c may have a film thickness that is substantially the same as the film thickness of the gate insulating film 41c. Also, for example, the gate insulating film 43c may have a film thickness within a range of one time or more and four times or less the film thickness of the gate insulating film 41c.

The pixel drive section 111 (see FIG. 1) of the imaging device 1 may be configured to individually control voltages to be supplied to the electric conductors 60 (back gate electrodes) and voltages to be supplied to the gate electrodes of the transistors in the wiring layer 210. For example, the voltages of the electric conductors 60 (back gate electrodes) may be set to be higher voltages than the voltages of the gate electrodes (front gate electrodes).

For example, in a case where effective capacitance of a gate insulating film (such as interlayer insulating film) below a channel region is smaller than effective capacitance of a gate insulating film above the channel region, the imaging device 1 may set voltages of the electric conductors 60 serving as the back gate electrodes to voltages that are higher than voltages of the front gate electrodes. This makes it possible to improve the ON/OFF ratios of the transistor FDG, the reset transistor RST, the selection transistor SEL, and the like, for example.

### (4-3. Modification Example 6)

In the above-described embodiments and modification examples, the configuration examples of the light detecting device have been described. However, the configuration of the light detecting device (imaging device 1) is not limited thereto. For example, layout positions, shapes, and the like of the respective transistors of the pixel P are not limited to those described in the above examples, but may be modified appropriately. As an example, the amplification transistor AMP, the transistor FDG, the reset transistor RST, and the selection transistor SEL may be provided in the wiring layer 210.

Alternatively, for example, as illustrated in the example of FIG. 5, the transistor FDG, the reset transistor RST, the selection transistor SEL, and the like may be allocated to the plurality of wiring layers including the first wiring layer 211 and the second wiring layer 212, for example. The electric conductors 60 may be disposed for the respective transistors allocated to the plurality of wiring layers.

The photoelectric conversion sections 12, the readout circuit 20, the pixel drive section 111, the signal processing section 112, and the like of the imaging device 1 may be provided in one substrate. For example, the pixel section 100, the pixel drive section 111, the signal processing section 112, and the like of the imaging device 1 may be provided in the substrate 101.

### 5. Application Example

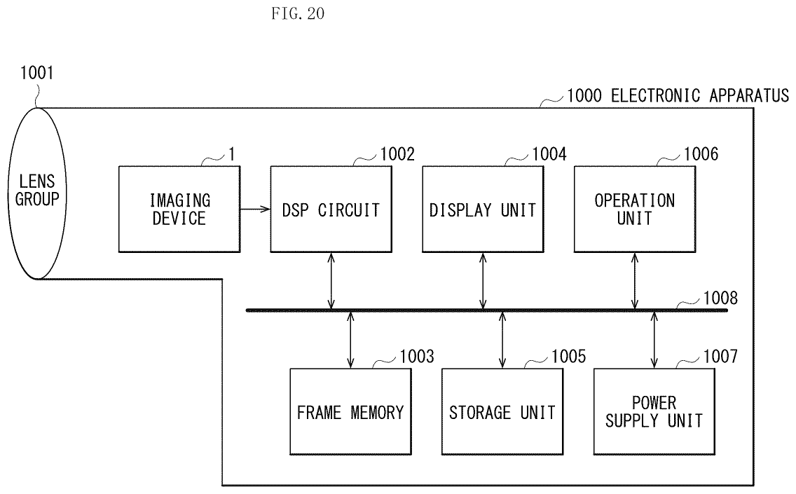

The above-described imaging device 1 or the like is applicable, for example, to any type of electronic apparatus with an imaging function including a camera system such as a digital still camera or a video camera, a mobile phone having an imaging function, and the like. FIG. 20 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operation unit 1006, and a power supply unit 1007. They are coupled to each other via a bus line 1008.

The lens group 1001 takes in incident light (image light) from a subject, and forms an image on an imaging surface of the imaging device 1. The imaging device 1 converts the amount of incident light formed as an image on the imaging surface by the lens group 1001 into electric signals on a pixel-by-pixel basis, and supplies the DSP circuit 1002 with the electric signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic EL (Electro Luminescence) panel, and records image data of a moving image or a still image captured by the imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 6. Practical Application Examples

### (Example of Practical Application to Mobile Body)

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

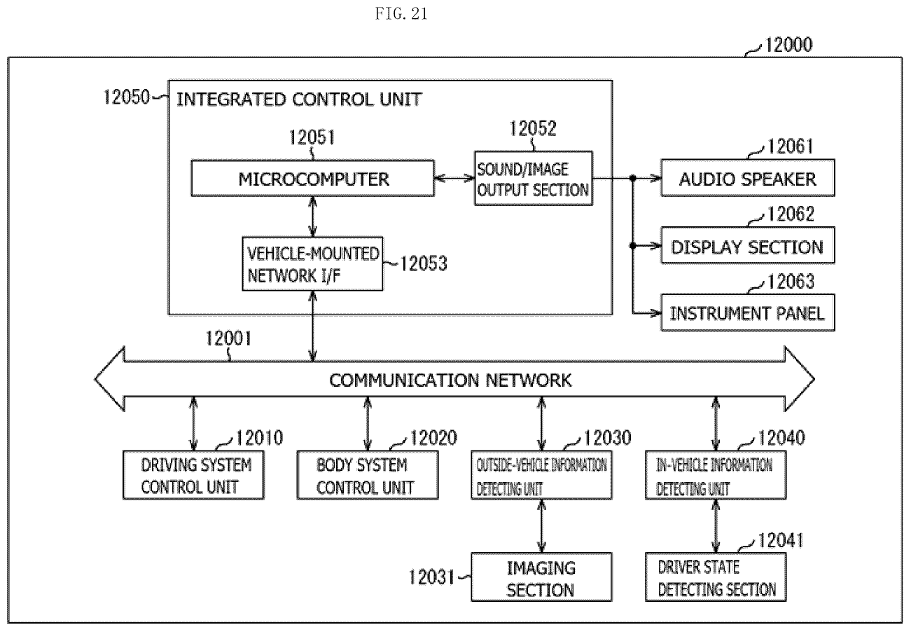

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

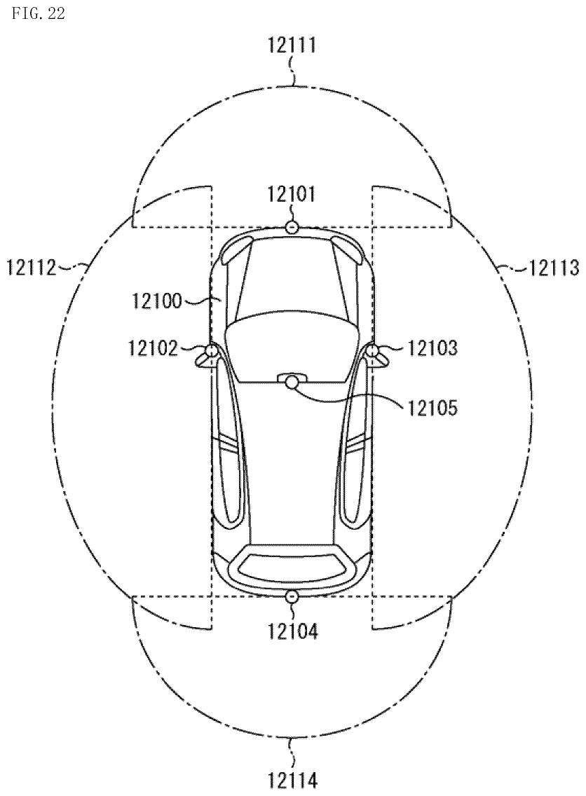

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1 or the like can be applied to the imaging section 12031. Applying the technology according to an embodiment of the present disclosure to the imaging section 12031 enables obtainment of a photographed image having high definition. This makes it possible to perform highly accurate control utilizing the photographed image in the mobile body control system.

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

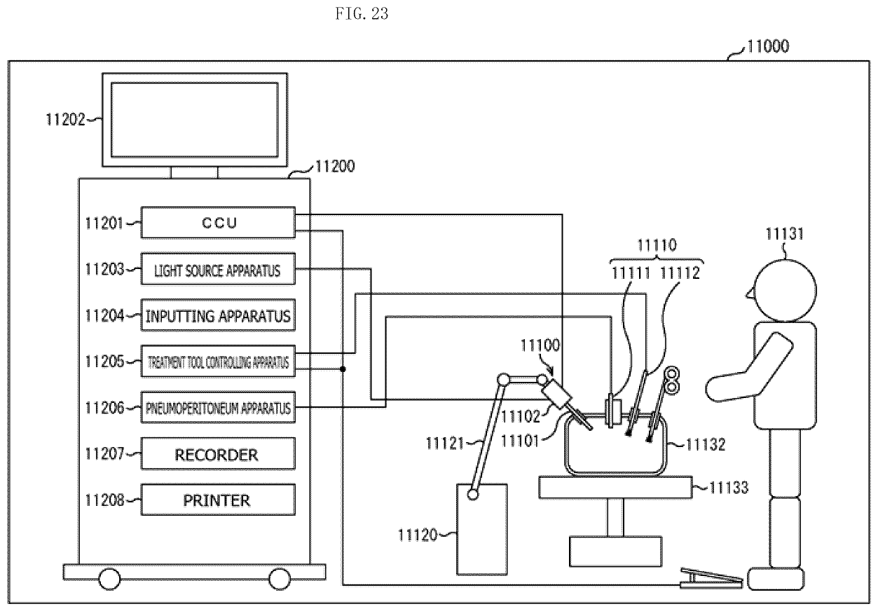

FIG. 23 is a view depicting an example of a schematic configuration of an endoscopic surgery system to which the technology according to an embodiment of the present disclosure (present technology) can be applied.

In FIG. 23, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

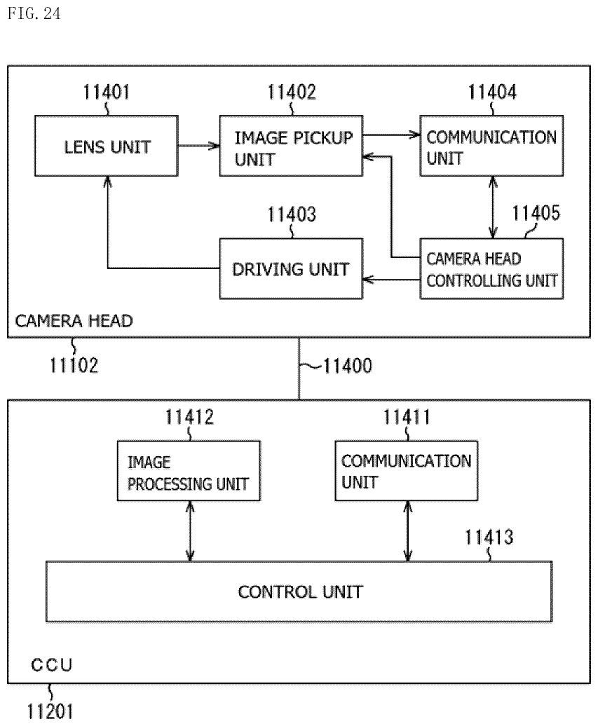

FIG. 24 is a block diagram depicting an example of a functional configuration of the camera head 11102 and the CCU 11201 depicted in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100 of the configurations described above. Applying the technology according to an embodiment of the present disclosure to the image pickup unit 11402 makes it possible to provide the endoscope 11100 having high definition.

Although the description has been given hereinabove of the present disclosure with reference to the embodiments, the modification examples, the application example, and the practical application examples, the present technology is not limited to the foregoing embodiments and the like, and may be modified in a wide variety of ways. For example, although the foregoing modification examples have been described as modification examples of the foregoing embodiments, the configurations of the respective modification examples may be combined as appropriate. For example, the present disclosure is not limited to a back side illumination image sensor, and is also applicable to a front side illumination image sensor.

In the foregoing embodiments and the like, the imaging device has been exemplified for description. However, it is sufficient for the light detecting device of the present disclosure to be, for example, a device that receives incident light and converts the light into electric charge. A signal to be outputted may be a signal of image information or a signal of information on a measured distance. The light detecting device (imaging device) is applicable to an image sensor, a distance measurement sensor, or the like.

The light detecting device according to the present disclosure is also applicable as a distance measurement sensor that enables distance measurement of a TOF (Time Of Flight) method. The light detecting device (imaging device) is also applicable as a sensor that is able to detect an event, e.g., an event-driven sensor (referred to as EVS (Event Vision Sensor), EDS (Event Driven Sensor), DVS (Dynamic Vision Sensor), etc.).

The present disclosure is applicable not only to the image sensor but also to various circuits and devices. The structure of the light detecting device illustrated in FIG. 4, FIG. 5, or the like is applicable to various semiconductor devices. Each semiconductor layer may be provided with any element (or circuit). For example, other elements or circuits may be formed in the semiconductor layer 110 instead of the photoelectric conversion elements. The semiconductor layer 110 and the semiconductor layer 120 may be provided with a memory, a sensor circuit, a power supply circuit, an amplification circuit, an interface circuit, or the like. The configurations of the circuits formed in the respective layers and layouts of the respective layers may be modified appropriately. The present disclosure is applicable to various electronic apparatuses as the semiconductor devices.

The light detecting device according to an embodiment of the present disclosure includes: the first substrate including the photoelectric conversion element and the readout circuit; and the second substrate that is stacked on the first substrate. The first substrate includes a semiconductor layer and a wiring layer. The readout circuit includes the first transistor provided in the wiring layer. Therefore, it becomes possible to achieve the light detecting device having an advantage in miniaturization.

The light detecting device according to an embodiment of the present disclosure includes: the first substrate including the photoelectric conversion element and the readout circuit; and the second substrate that is stacked on the first substrate. The first substrate includes a semiconductor layer and a wiring layer. The readout circuit includes the first transistor provided in the wiring layer. The wiring layer includes the electric conductor provided between the semiconductor layer and the first transistor. The first transistor is provided to be stacked with respect to the electric conductor. Therefore, it becomes possible to achieve the light detecting device having an advantage in miniaturization.

It is to be noted that effects described herein are merely illustrative and are not limitative, and there may be other effects. In addition, the present technology may may also have the following configurations.

(1) A light detecting device including:

a first substrate including a photoelectric conversion element and a readout circuit, the photoelectric conversion element photoelectrically converting light, the readout circuit being configured to output a first signal based on electric charge converted by the photoelectric conversion element; and

a second substrate including a signal processing circuit configured to execute signal processing on the first signal, the second substrate being stacked on the first substrate, in which the first substrate includes a semiconductor layer and a wiring layer, and

the readout circuit includes a first transistor provided in the wiring layer.

(2) The light detecting device according to (1), in which the first transistor includes a thin-film transistor.

(3) The light detecting device according to (1) or (2), in which the first transistor includes an amplification transistor, a selection transistor, a reset transistor, or a switching transistor.

(4) The light detecting device according to any one of (1) to (3), further including: a floating diffusion; and

a transfer transistor provided on a side of a first surface of the semiconductor layer, the transfer transistor being configured to transfer the electric charge converted by the photoelectric conversion element to the floating diffusion.

(5) The light detecting device according to (4), further including wiring provided in the wiring layer, the wiring including a metal material, in which

the transfer transistor is electrically coupled to the first transistor through the wiring.

(6) The light detecting device according to any one of (1) to (5), in which

the readout circuit includes a plurality of transistors including the first transistor, and

the plurality of transistors is provided in the wiring layer.

(7) The light detecting device according to any one of (1) to (6), in which

the readout circuit includes a plurality of transistors including the first transistor,

a portion of the plurality of transistors is provided on the side of the first surface of the semiconductor layer, and

another portion of the plurality of transistors is provided in the wiring layer.

(8) The light detecting device according to (7), in which the plurality of transistors includes an amplification transistor provided on the side of the first surface of the semiconductor layer.

(9) The light detecting device according to any one of (1) to (8), in which the first transistor is configured as a vertical transistor.

(10) The light detecting device according to any one of (1) to (9), in which

the readout circuit includes a second transistor provided in the wiring layer, and

the first transistor and the second transistor are provided in tiers different from each other.

(11) The light detecting device according to (10), in which the wiring layer includes a first wiring layer provided with the first transistor, and a second wiring layer provided with the second transistor, the second wiring layer being positioned on the first wiring layer.

(12) The light detecting device according to any one of (1) to (11), in which the signal processing circuit includes an AD conversion circuit configured to convert the first signal into a digital signal.

(13) The light detecting device according to any one of (1) to (12), in which

the semiconductor layer has the first surface and a second surface on a side opposite to the first surface,

the wiring layer is stacked on the first surface of the semiconductor layer, and

the photoelectric conversion element is provided between the first surface and the second surface of the semiconductor layer.

(14) The light detecting device according to (13), further including a lens provided on a side of the second surface of the semiconductor layer, in which

the photoelectric conversion element photoelectrically converts light incident through the lens.

(15) The light detecting device according to any one of (1) to (14), in which the wiring layer includes an electric conductor provided between the semiconductor layer and the first transistor, and

the first transistor is provided to be stacked with respect to the electric conductor.

(16) The light detecting device according to (15), in which the electric conductor includes a shield section that is to be supplied with a predetermined potential.

(17) The light detecting device according to (15) or (16), further including:

a well of a first electrical conductivity type that is provided in the semiconductor layer; and

a semiconductor region of the first electrical conductivity type that is provided in the well, in which

the electric conductor is electrically coupled to the semiconductor region.

(18) The light detecting device according to (15) or (16), in which

the wiring layer includes wiring that is to be supplied with a ground potential, and

the electric conductor is electrically coupled to the wiring.

(19) The light detecting device according to (15) or (16), further including:

a well of a first electrical conductivity type that is provided in the semiconductor layer; and

a semiconductor region of the first electrical conductivity type that is provided in the well, in which

the wiring layer includes wiring that is to be supplied with a ground potential, and the electric conductor is electrically coupled to the semiconductor region and the wiring.

(20) The light detecting device according to any one of (15) to (19), in which

the electric conductor is provided below a channel region of the first transistor, and

the electric conductor has a size that is larger than a size of the channel region.

(21) The light detecting device according to any one of (15) to (20), in which

the readout circuit includes a third transistor provided on the side of the first surface of the semiconductor layer, and

the electric conductor is provided between the third transistor and the first transistor.

(22) The light detecting device according to (21), in which the electric conductor is provided between a gate electrode of the third transistor and the channel region of the first transistor.

(23) The light detecting device according to (21) or (22), in which the third transistor includes a transfer transistor or an amplification transistor.

(24) The light detecting device according to (15) or (16), in which

the first transistor includes a channel region, a gate electrode provided above the channel region, and a gate insulating film provided between the channel region and the gate electrode,

the electric conductor is provided below the channel region of the first transistor, and

the wiring layer includes an insulating film provided between the channel region and the electric conductor.

(25) The light detecting device according to (24), in which the electric conductor is electrically coupled to the gate electrode of the first transistor.

(26) The light detecting device according to (25), in which the insulating film has a film thickness within a range of one time or more and two times or less a film thickness of the gate electrode.

(27) The light detecting device according to (24), in which the electric conductor and the gate electrode are electrically coupled to wirings different from each other.

(28) The light detecting device according to (27), in which the insulating film has a film thickness within a range of one time or more and four times or less a film thickness of the gate electrode.

(29) An electronic apparatus including:

an optical system; and

a light detecting device that receives light transmitted though the optical system,

the light detecting device including
a first substrate including a photoelectric conversion element and a readout circuit, the photoelectric conversion element photoelectrically converting light, the readout circuit being configured to output a first signal based on electric charge converted by the photoelectric conversion element, and
   a second substrate including a signal processing circuit configured to execute signal processing on the first signal, the second substrate being stacked on the first substrate, in which

the first substrate includes a semiconductor layer and a wiring layer, and

the readout circuit includes a first transistor provided in the wiring layer.

The present application claims the benefit of Japanese Priority Patent Application JP2023-065186 filed with the Japan Patent Office on Apr. 12, 2023 and Japanese Priority Patent Application JP2023-205645 filed with the Japan Patent Office on Dec. 5, 2023, the entire contents of both of which are incorporated herein by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A light detecting device, comprising:
a first substrate including a photoelectric conversion element and a readout circuit, the photoelectric conversion element photoelectrically converting light, the readout circuit being configured to output a first signal based on electric charge converted by the photoelectric conversion element; and
a second substrate including a signal processing circuit configured to execute signal processing on the first signal, the second substrate being stacked on the first substrate, wherein
the first substrate includes a semiconductor layer and a wiring layer, and
the readout circuit includes a first transistor provided in the wiring layer.

2. The light detecting device according to claim 1, wherein the first transistor comprises a thin-film transistor.

3. The light detecting device according to claim 1, wherein the first transistor comprises an amplification transistor, a selection transistor, a reset transistor, or a switching transistor.

4. The light detecting device according to claim 1, further comprising:
a floating diffusion; and
a transfer transistor provided on a side of a first surface of the semiconductor layer, the transfer transistor being configured to transfer the electric charge converted by the photoelectric conversion element to the floating diffusion.

5. The light detecting device according to claim 4, further comprising wiring provided in the wiring layer, the wiring including a metal material, wherein
the transfer transistor is electrically coupled to the first transistor through the wiring.

6. The light detecting device according to claim 1, wherein
the readout circuit includes a plurality of transistors including the first transistor, and
the plurality of transistors is provided in the wiring layer.

7. The light detecting device according to claim 1, wherein
the readout circuit includes a plurality of transistors including the first transistor,
a portion of the plurality of transistors is provided on a side of a first surface of the semiconductor layer, and
another portion of the plurality of transistors is provided in the wiring layer.

8. The light detecting device according to claim 7, wherein the plurality of transistors includes an amplification transistor provided on the side of the first surface of the semiconductor layer.

9. The light detecting device according to claim 1, wherein the first transistor is configured as a vertical transistor.

10. The light detecting device according to claim 1, wherein
the readout circuit includes a second transistor provided in the wiring layer, and
the first transistor and the second transistor are provided in tiers different from each other.

11. The light detecting device according to claim 10, wherein the wiring layer includes a first wiring layer provided with the first transistor, and a second wiring layer provided with the second transistor, the second wiring layer being positioned on the first wiring layer.

12. The light detecting device according to claim 1, wherein the signal processing circuit includes an AD conversion circuit configured to convert the first signal into a digital signal.

13. The light detecting device according to claim 1, wherein
the semiconductor layer has a first surface and a second surface on a side opposite to the first surface,
the wiring layer is stacked on the first surface of the semiconductor layer, and
the photoelectric conversion element is provided between the first surface and the second surface of the semiconductor layer.

14. The light detecting device according to claim 13,
further comprising a lens provided on a side of the second surface of the semiconductor layer, wherein
the photoelectric conversion element photoelectrically converts light incident through the lens.

15. The light detecting device according to claim 1, wherein
the wiring layer includes an electric conductor provided between the semiconductor layer and the first transistor, and
the first transistor is provided to be stacked with respect to the electric conductor.

16. The light detecting device according to claim 15, wherein the electric conductor comprises a shield section that is to be supplied with a predetermined potential.

17. The light detecting device according to claim 15, further comprising:
a well of a first electrical conductivity type that is provided in the semiconductor layer; and
a semiconductor region of the first electrical conductivity type that is provided in the well, wherein
the electric conductor is electrically coupled to the semiconductor region.

18. The light detecting device according to claim 15, wherein
the wiring layer includes wiring that is to be supplied with a ground potential, and
the electric conductor is electrically coupled to the wiring.

19. The light detecting device according to claim 15, further comprising:
a well of a first electrical conductivity type that is provided in the semiconductor layer; and
a semiconductor region of the first electrical conductivity type that is provided in the well, wherein
the wiring layer includes wiring that is to be supplied with a ground potential, and
the electric conductor is electrically coupled to the semiconductor region and the wiring.

20. The light detecting device according to claim 15, wherein
the electric conductor is provided below a channel region of the first transistor, and
the electric conductor has a size that is larger than a size of the channel region.

21. The light detecting device according to claim 15, wherein
the readout circuit includes a third transistor provided on a side of a first surface of the semiconductor layer, and
the electric conductor is provided between the third transistor and the first transistor.

22. The light detecting device according to claim 21, wherein the electric conductor is provided between a gate electrode of the third transistor and a channel region of the first transistor.

23. The light detecting device according to claim 21, wherein the third transistor comprises a transfer transistor or an amplification transistor.

24. The light detecting device according to claim 15, wherein
the first transistor includes a channel region, a gate electrode provided above the channel region, and a gate insulating film provided between the channel region and the gate electrode,
the electric conductor is provided below the channel region of the first transistor, and
the wiring layer includes an insulating film provided between the channel region and the electric conductor.

25. The light detecting device according to claim 24, wherein the electric conductor is electrically coupled to the gate electrode of the first transistor.

26. The light detecting device according to claim 25, wherein the insulating film has a film thickness within a range of one time or more and two times or less a film thickness of the gate electrode.

27. The light detecting device according to claim 24, wherein the electric conductor and the gate electrode are electrically coupled to wirings different from each other.

28. The light detecting device according to claim 27, wherein the insulating film has a film thickness within a range of one time or more and four times or less a film thickness of the gate electrode.

29. An electronic apparatus, comprising:
an optical system; and
a light detecting device that receives light transmitted though the optical system,
the light detecting device including
a first substrate including a photoelectric conversion element and a readout circuit, the photoelectric conversion element photoelectrically converting light, the readout circuit being configured to output a first signal based on electric charge converted by the photoelectric conversion element, and
a second substrate including a signal processing circuit configured to execute signal processing on the first signal, the second substrate being stacked on the first substrate, wherein
the first substrate includes a semiconductor layer and a wiring layer, and
the readout circuit includes a first transistor provided in the wiring layer.
